(19) United States
(12) Patent Application Publication
(10) Pub. No.: US 2010/0024859 A1
(43) Pub. Date: Feb. 4, 2010

(54) THERMOELECTRIC POWER GENERATOR FOR VARIABLE THERMAL POWER SOURCE

(75) Inventors: Lon E. Bell, Altadena, CA (US); Douglas T. Crane, Altadena, CA (US)

Correspondence Address: KNOBBE MARTENS OLSON & BEAR LLP, 2040 MAIN STREET, FOURTEENTH FLOOR, IRVINE, CA, 92614, US

(73) Assignee: BSST, LLC., Irwindale, CA (US)

(21) Appl. No.: 12/252,314

(22) Filed: Oct. 15, 2008

Related U.S. Application Data
(60) Provisional application No. 61/084,606, filed on Jul. 29, 2008.

(51) Int. Cl. H01L 35/02

(52) U.S. Cl. 136/201; 136/205

(57) ABSTRACT

A thermoelectric generator includes a first thermoelectric segment including at least one thermoelectric module. The first thermoelectric segment has a working fluid flowing therethrough with a fluid pressure. The thermoelectric generator further includes a second thermoelectric segment including at least one thermoelectric module. The second thermoelectric segment is configurable to allow the working fluid to flow therethrough. The thermoelectric generator further includes at least a first variable flow element movable upon application of the fluid pressure to the first variable flow element. The first variable flow element modifies a flow resistance of the second thermoelectric segment to flow of the working fluid therethrough.

### CLAIM OF PRIORITY

This application claims the benefit of priority to U.S. Provisional Patent Application No. 61/084,606 filed Jul. 29, 2008 which is incorporated in its entirety by reference herein.

### STATEMENT REGARDING FEDERALLY SPONSORED R&D

The U.S. Government may claim to have certain rights in this invention or parts of this invention under the terms of Contract No. DE-FC26-04NT42279 awarded by the U.S. Department of Energy.

### BACKGROUND OF THE INVENTION

1. Field of the Invention

The present application relates to the field of thermoelectric power generation, and more particularly to systems for improving the generation of power from thermoelectrics where the heat source varies in temperature and heat flux.

2. Description of the Related Art

Thermoelectrics are solid state devices that operate to become cold on one side and hot on the other side when electrical current passes through. They can also generate power by maintaining a temperature differential across the thermoelectric. Under many operating conditions, however, thermoelectric power generators are exposed to a combination of changing heat fluxes, hot side heat source temperatures, cold side heat rejection temperatures, and other variable conditions. In addition, the device properties, such as TE thermal conductance, Figure of Merit Z, heat exchanger performance all have a range of manufacturing tolerances that combine to, in general, reduce device performance. As a result, performance varies and operation at a predetermined set point can lead to performance degradation compared to design values.

Any process that consumes energy that is not 100% efficient generates waste energy, usually in the form of heat. For example, internal combustion engines generate a substantial amount of waste heat. In order to improve the efficiency of the internal combustion engine, such as in automobiles, various ways to capture some of this waste heat and convert it to a useful form have been considered. Placing thermoelectrics on the exhaust system of an automobile has been contemplated (See U.S. Pat. No. 6,986,247 entitled Thermoelectric Catalytic Power Generator with Preheat). However, because the exhaust system varies greatly in heat and heat flux, providing a system that is effective has been illusive. By way of example, compared to optimal performance, degradation in automobile waste heat recovery system performance can be very significant, amounting to at least 30%.

### SUMMARY OF THE INVENTION

In certain embodiments, a thermoelectric generator comprises a first thermoelectric segment comprising at least one thermoelectric module. The first thermoelectric segment has a working fluid flowing therethrough with a fluid pressure. The thermoelectric generator further comprises a second thermoelectric segment comprising at least one thermoelectric module. The second thermoelectric segment is configurable to allow the working fluid to flow therethrough. The thermoelectric generator further comprises at least a first variable flow element movable upon application of the fluid pressure to the first variable flow element. The first variable flow element modifies a flow resistance of the second thermoelectric segment to flow of the working fluid therethrough.

In certain embodiments, a thermoelectric generator comprises a first thermoelectric segment having at least one thermoelectric module and a second thermoelectric segment having at least one thermoelectric module. The thermoelectric generator further comprises a movable element positionable in multiple positions comprising a first position, a second position, and a third position. The first position permits flow of a working fluid through the first thermoelectric segment while simultaneously permitting flow of the working fluid through the second thermoelectric segment. The second position inhibits flow of the working fluid through the first thermoelectric segment while simultaneously permitting flow of the working fluid through the second thermoelectric segment. The third position inhibits flow of the working fluid through the first thermoelectric segment while simultaneously inhibiting flow of the working fluid through the second thermoelectric segment.

In certain embodiments, a thermoelectric generator comprises a plurality of thermoelectric segments comprising a first thermoelectric segment, a second thermoelectric segment, and a conduit. At least two of the first thermoelectric segment, the second thermoelectric segment, and the conduit each comprises at least one thermoelectric module. The thermoelectric generator further comprises a movable element positionable in multiple positions comprising a first position, a second position, a third position, and a fourth position. The first position permits flow of a working fluid through the first thermoelectric segment while simultaneously permitting flow of the working fluid through the second thermoelectric segment and simultaneously permitting flow of the working fluid through the conduit. The second position inhibits flow of the working fluid through the first thermoelectric segment while simultaneously permitting flow of the working fluid through the second thermoelectric segment and simultaneously permitting flow of the working fluid through the conduit. The third position inhibits flow of the working fluid through the first thermoelectric segment while simultaneously inhibiting flow of the working fluid through the second thermoelectric segment and simultaneously permitting flow of the working fluid through the conduit. The fourth position inhibits flow of the working fluid through the first thermoelectric segment while simultaneously inhibiting flow of the working fluid through the second thermoelectric segment and simultaneously inhibiting flow of the working fluid through the conduit.

In certain embodiments, a method operates a plurality of thermoelectric modules. The method comprises flowing a working fluid through a first thermoelectric segment comprising at least a first thermoelectric module. The fluid has a fluid pressure. The method further comprises flowing the working fluid through a second thermoelectric segment comprising at least a second thermoelectric module when the fluid pressure of the fluid exceeds a threshold pressure. The method further comprises inhibiting the flow of the working fluid through the second thermoelectric segment when the fluid pressure of the fluid does not exceed the threshold pressure.

In certain embodiments, a method operates a plurality of thermoelectric modules. The method comprises varying both the flow of working fluid through a first thermoelectric segment comprising at least a first thermoelectric module and the flow of working fluid through a second thermoelectric segment comprising at least a second thermoelectric module by selecting a position for a moveable element from a plurality of positions comprising a first position, a second position, and a third position. The first position permits flow through the first thermoelectric segment while simultaneously permitting flow through the second thermoelectric segment. The second position inhibits flow through the first thermoelectric segment while simultaneously permitting flow through the second thermoelectric segment. The third position inhibits flow through the first thermoelectric segment while simultaneously inhibiting flow through the second thermoelectric segment.

In certain embodiments, a thermoelectric generator comprises a first thermoelectric segment comprising at least one thermoelectric module: The first thermoelectric segment has a working fluid flowing therethrough, and the fluid has a temperature. The thermoelectric generator further comprises a second thermoelectric segment comprising at least one thermoelectric module. The second thermoelectric segment is configurable to allow the working fluid to flow therethrough. The thermoelectric generator further comprises at least a first variable flow element configured to move in response to a temperature of the first variable flow element. The first variable flow element modifies a flow resistance of the second thermoelectric segment to flow of the working fluid therethrough.

In certain embodiments, a method operates a plurality of thermoelectric modules. The method comprises flowing a working fluid through a first thermoelectric segment comprising at least a first thermoelectric module, and the working fluid has a temperature. The method further comprises flowing the working fluid through a second thermoelectric segment comprising at least a second thermoelectric module when the temperature of the working fluid exceeds a threshold temperature. The method further comprises inhibiting the flow of the working fluid through the second thermoelectric segment when the temperature does not exceed the threshold temperature.

In certain embodiments, a thermoelectric generator comprises an input portion configured to allow a working fluid to flow therethrough. The thermoelectric generator further comprises an output portion configured to allow the working fluid to flow therethrough. The thermoelectric generator further comprises a plurality of elongate thermoelectric segments substantially parallel to one another. At least one of the thermoelectric segments comprises at least one thermoelectric module. Each thermoelectric segment is configurable to allow the working fluid to flow therethrough from the input portion to the output portion. The thermoelectric generator further comprises at least one movable element positionable to allow flow of the working fluid through at least a first thermoelectric segment of the plurality of thermoelectric segments and to inhibit flow of the working fluid through at least a second thermoelectric segment of the plurality of thermoelectric segments.

### BRIEF DESCRIPTION OF THE DRAWINGS

FIG. 1 depicts a generalized block diagram of a conventional power generation system using thermoelectrics.

FIG. 2 is a graph illustrating voltage relative to current with an overlay of power output for a thermoelectric module at various operating temperatures.

FIG. 3 is a graph illustrating efficiency relative to the hot side temperature of a thermoelectric module, identifying operating points at theoretical peak efficiency and at peak theoretical power.

FIG. 4 is a graph illustrating heat flux at the hot side of a thermoelectric module relative to the current through the thermoelectric module at various hot-side operating temperatures.

FIG. 5 is a graph illustrating voltage relative to current with an overlay for power for a thermoelectric module.

FIG. 6 is a graph illustrating voltage relative to current with an overlay for power, for a thermoelectric power generation system operating with improved power production.

FIG. 7 depicts a portion of an thermoelectric module.

FIG. 8 is a graph illustrating yet further operation conditions depicting voltage relative to current with an overlay for power for a thermoelectric module in accordance with FIG. 7.

FIG. 9 depicts an embodiment of a thermoelectric power generator for use in generating power from a heat source.

FIG. 10 depicts one embodiment for the thermoelectric generator component of the power generation system of FIG. 9.

FIG. 11 depicts an alternative embodiment for the thermoelectric generator component of the power generation system of FIG. 9.

FIG. 12A depicts an embodiment of a thermoelectric generator as viewed from one angle

FIG. 12B depicts the same embodiment of a thermoelectric generator depicted in FIG. 12A as viewed from a different angle.

FIG. 13A depicts an embodiment of a thermoelectric generator as viewed from one angle

FIG. 13B depicts the same embodiment of a thermoelectric generator depicted in FIG. 13A as viewed from a different angle.

FIG. 14 depicts an embodiment of a thermoelectric generator.

FIG. 15 depicts an embodiment of a thermoelectric generator, similar to the embodiment depicted in FIG. 14, but further depicting a controller and thermoelectric modules connected in series that can be selectively disconnected by the controller.

FIG. 16 schematically illustrates a scheme for fluidically connecting thermoelectric segments.

FIG. 17 schematically illustrates another scheme for fluidically connecting thermoelectric segments.

FIG. 18 is a flow diagram of an example method of operating a plurality of thermoelectric modules.

FIG. 19 depicts another embodiment of a thermoelectric generator.

FIG. 20 is a flow diagram of an example method of operating a plurality of thermoelectric modules.

FIG. 21 depicts one embodiment of a bi-metal temperature responsive variable flow element.

FIG. 22 is a flow diagram of an example method of operating a plurality of thermoelectric modules.

### DETAILED DESCRIPTION OF THE PREFERRED EMBODIMENT

Certain embodiments described herein relate to a thermoelectric power generation system which is capable of generating power more efficiently than a standard system, particularly suited for a thermal power source with variable thermal output. Certain embodiments are useful for many waste heat recovery, waste heat harvesting and power generation applications. However, in order to illustrate various aspects of the thermoelectric power generation system, a specific embodiment is described which generates electrical power from thermal power contained in the exhaust of a vehicle. This particular example illustrates the advantage of designing the power generation system to monitor and control the conditions that affect power production, even under varying operating conditions. Substantial improvements can be derived by controlling TE couple properties (for example as described in U.S. Pat. No. 6,672,076, entitled “Efficiency Thermoelectrics Utilizing Convective Heat Flow” and incorporated in its entirety by reference herein), working fluid mass flow, operating current (or voltage), TE element form factor and system capacity. Improvements can also be obtained by designing the thermoelectric system to have thermal isolation in the direction of flow as described in U.S. Pat. No. 6,539,725 entitled “Efficiency Thermoelectric Utilizing Thermal Isolation,” which is also incorporated in its entirety by reference herein. Thus, in one embodiment, it is desirable to control the number of thermoelectric couples activated to produce power, to control the cooling conditions, to control cooling fluid flow rate, and/or to control temperatures and TE material properties.

While automotive waste heat recovery is used as an example, certain embodiments are applicable to improve the performance of power generation, waste heat recovery, cogeneration, power production augmentation, and other uses. Certain embodiments can be used to utilize waste heat in the engine coolant, transmission oil, brakes, catalytic converters, and other sources in cars, trucks, busses, trains, aircraft and other vehicles. Similarly, waste heat from chemical processes, glass manufacture, cement manufacture, and other industrial processes can be utilized. Other sources of waste heat such as from biowaste, trash incineration, burn off from refuse dumps, oil well burn off, can be used. Power can be produced from solar, nuclear, geothermal and other heat sources. Application to portable, primary, standby, emergency, remote, personal and other power production devices are also compatible with certain embodiments described herein. In addition, the certain embodiments can be coupled to other devices in cogeneration systems, such as photovoltaic, fuel cell, fuel cell reformers, nuclear, internal, external and catalytic combustors, and other advantageous cogeneration systems. The number of TE modules described in any embodiment herein is not of any import, but is merely selected to illustrate the embodiment.

Although examples are presented to show how various configurations can be employed to achieve the desired improvements, the particular embodiments are only illustrative and not intended in any way to restrict the inventions presented. The term thermoelectric or thermoelectric element as used herein can mean individual thermoelectric elements as well as a collection of elements or arrays of elements. Further, the term thermoelectric is not restrictive, but used to include thermoionic and all other solid-state cooling and heating devices. In addition, the terms hot and cool or cold are relative to each other and do not indicate any particular temperature relative to room temperature or the like. Finally, the term working fluid is not limited to a single fluid, but can refer to one or more working fluids.

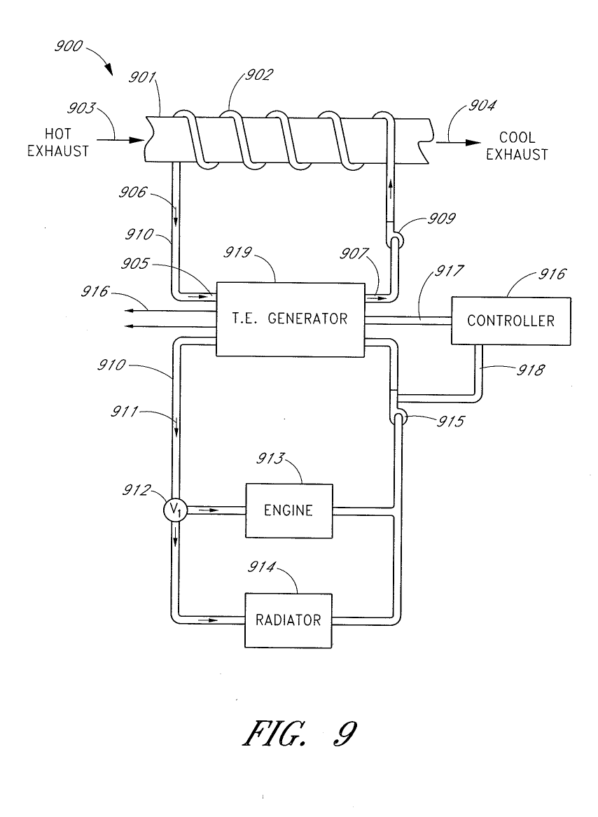

The particular illustrations herein depict just a few possible examples of a TE generator in accordance with certain embodiments described herein. Other variations are possible and compatible with various embodiments. The system could consist of at least 2, but any number of TE modules that can operate at least partially independent of each other. In some example TE generators, each such TE module has a different capacity, as depicted by being different sizes as described in more detail in connection with FIG. 10. Having TE modules of different capacity, and the ability to switch thermal power to activate or remove each TE module independently from operation, allows the controller explained herein to adapt to substantially changing operational conditions.

Automotive exhaust provides waste heat from the engine. This waste heat can be used as a source of thermal power for generation of electrical power using thermoelectric generators. This particular application is chosen to illustrate the advantages of certain embodiments disclosed herein because it provides a good example of highly variable operating conditions, in which thermal power output of the exhaust varies continually. The actual temperature and heat flux of the exhaust, which is used as the input thermal power source for the thermoelectric power generation system, varies substantially. Exhaust temperatures at the outlet of a catalytic converter typically vary from 450 to 650° C. and exhaust heat flux varies often more than a factor of 10 between idle and rapid acceleration conditions. Thus, this particular application provides an adequate illustration of the uses of certain embodiments disclosed herein.

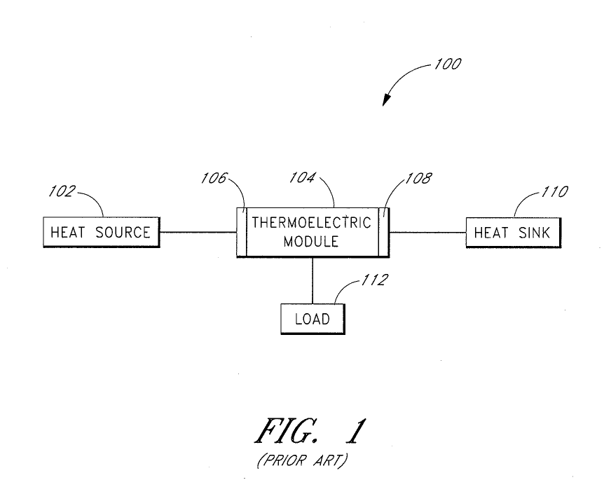

FIG. 1 illustrates a simple thermoelectric (“TE”) power generation system 100. A thermal power source 102 provides heat to the hot side of a TE module 104. The TE module 104 may have a hot-side heat exchanger 106 and a cold-side heat exchanger 108. The cold-side heat exchanger could provide a thermal power conduit for heat not used in the formation of electricity by the TE module 104. Typically, a heat sink 110, such as air or a liquid coolant, circulates to eliminate the waste heat from the TE generator. The temperature gradient across the TE module 104 generates electrical current to power a load 112.

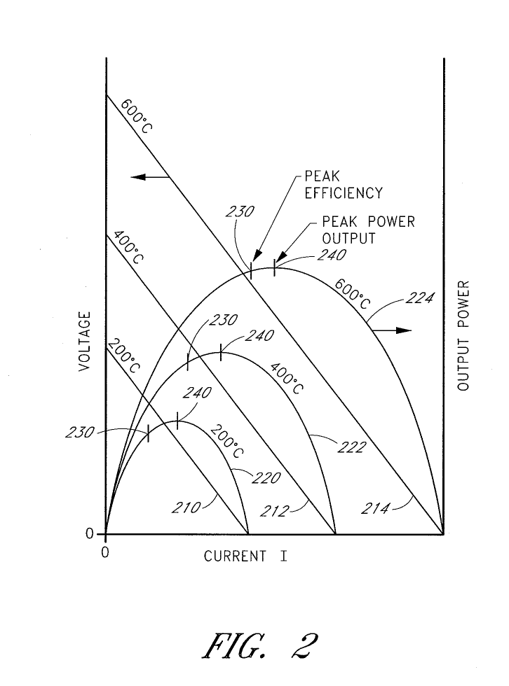

Such a TE power generator 100 is typically designed for a steady state operation, in order to maintain the thermoelectric operation at or substantially close to peak efficiency. When conditions vary from these design criteria, the thermoelectric efficiency drops, or can even become negative, as further explained with reference to FIGS. 2-4.

Some brief background on thermoelectric efficiency with reference to FIGS. 2-4 is described to facilitate an understanding of the benefits of the embodiments disclosed herein. An exemplary power generation performance curve for a TE material with ZTₐᵥₑ=1 (the temperature weighted average ZT of a TE element) is shown in FIG. 2. In FIG. 2, the voltage output V(I), of the TE element assembly is plotted as a function of the current output, I, in three lines 210, 212, 214 for three hot side temperatures T₁ at 200° C., T₂ at 400° C. and T₃ at 600° C. Overlaid on the graph are corresponding power output curves 220, 222, 224, which correspond to the power from the thermoelectric at the particular point in the graph calculated in conventional fashion as power output, P, where P=I*V(I).

For illustrative purposes, the cold-side temperature is assumed to be the same for all three hot side temperatures. As seen in FIG. 2, the power is a function of voltage and current. Ideally, the thermoelectric is operated at either peak efficiency 230 or peak power 240, or some trade-off between the two. If thermal flux from the heat source increases, but the temperature remains the same for the hot side of the thermoelectric (for example, the exhaust flow rate increases but the temperature does not change), then the maximum electrical power output is fixed as shown in FIG. 2. Excess available heat flux, at the same hot side temperature, cannot flow through the thermoelectric without an increase in current, I. However, as illustrated in the power curves 220, 222, 224, an increase in current for the same hot-side temperature would actually decrease the power output P. Thus, additional thermal power does not contribute to higher electrical power output, unless the hot side temperature of the thermoelectric can be increased. Similarly, if less thermal flux than that for optimum power output (Pₘ) 240 is available, peak power is not realized. This also holds true for operation substantially at optimum efficiency. For generators operating in conditions that are not steady, a thermoelectric system designed to monitor and control the factors that influence performance is advantageous and can be used to modify generator output and improve performance.

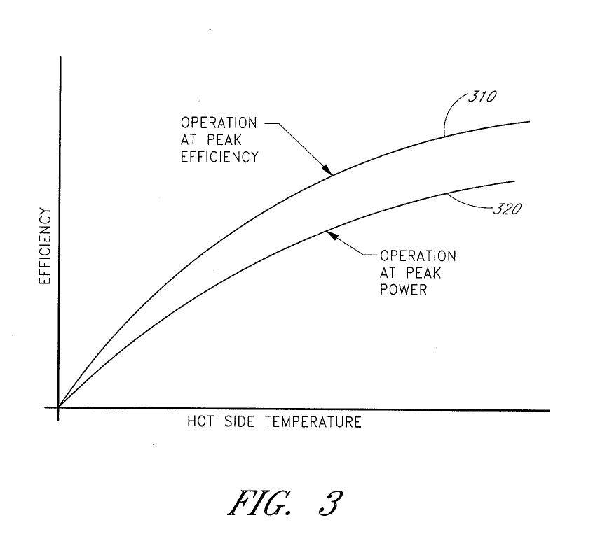

The relationship between efficiency and hot side temperature for operation at peak efficiency and peak power is illustrated in FIG. 3. A curve illustrating operation at peak efficiency 310 and a curve illustrating operation at peak power 320 are illustrated. The heat flux, Qₕ, through the TE assembly varies with current, I, for fixed hot and cold side temperatures. As a result, peak efficiency occurs at voltages and currents that differ from those for peak power output. It should be noted that the heat flux, Qₕ, is a function of the TE material and device properties, and has a value defined by these properties and the current, I. If conditions vary, such as by changing load current, I, the efficiency and Q change.

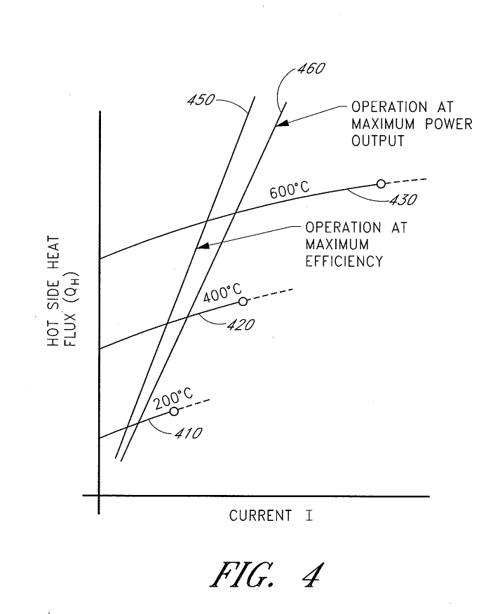

An illustration of the change in Qₕ with current, I, is provided in FIG. 4. In this illustration three heat flux curves 410, 420, 430 are illustrated representing operation of the thermoelectric at three different hot side temperatures T₁ at 200° C., T₂ at 400° C. and T₃ at 600° C. Overlaid on these curves is peak operating efficiency curve 450 and a peak operating power curve 460. The dashed portion three heat flux curves 410, 420, 430, representing of the heat flux, Qₕ, indicates operation at currents, I, sufficiently large that the voltage, (and hence power output) is negative.

The performance noted above does have the characteristic that close to the peak value of power output the performance reduction is small for moderate changes in current, I and Qₕ, so performance is not degraded appreciably for modest changes in Qₕ. However, several other factors which interact with the thermal power control system contribute substantially to reductions in system efficiency. These factors are discussed below and the mechanisms and designs that reduce their impact on efficiency are described and are part of the present invention.

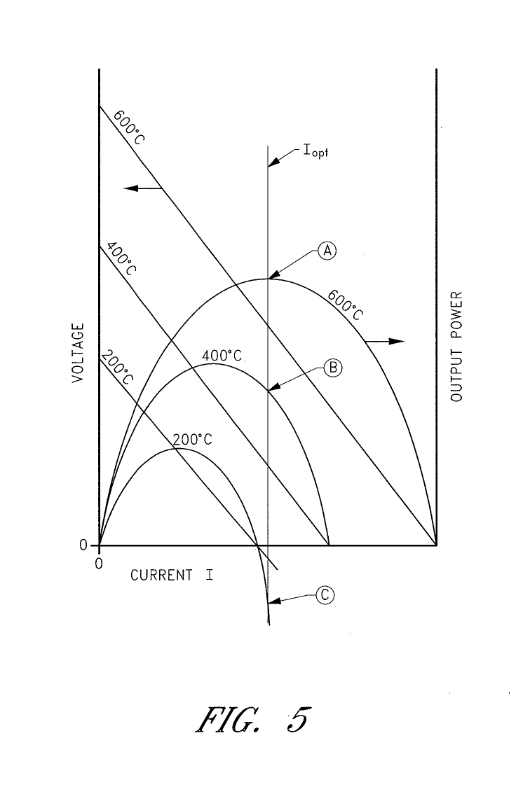

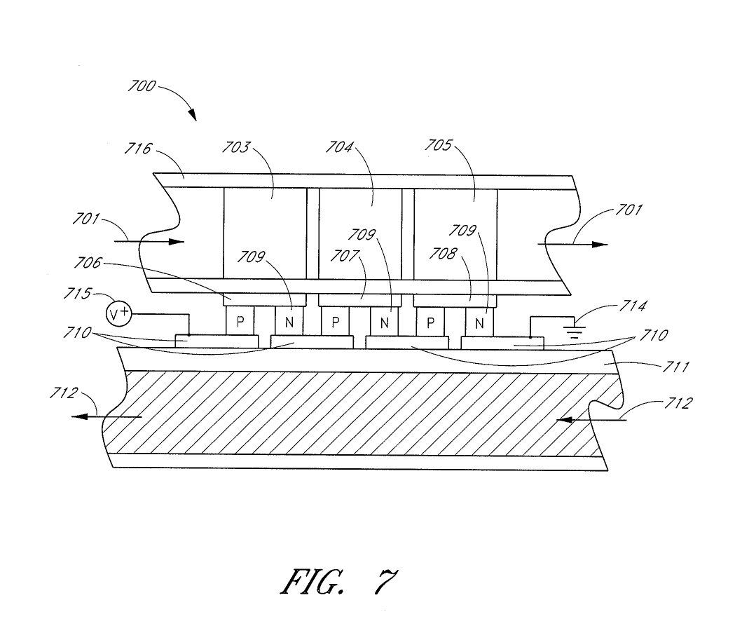

FIG. 5 is a representative plot showing the character of output voltage and power relative to current for either a single TE element (unicouple), N- and P-pair of TE elements (couple), or a group of couples. Values for a fixed cold-side temperature at different hot-side temperatures are given. Often it is advantageous for several such elements to be connected electrically in series to form a power generation module. Often it is desirable to operate the module so that at one end, a hot working fluid enters and passes through (or by) heat exchangers in thermal contact with the hot side of the TE elements of a power generator, as shown in FIG. 7 (which will be described in detail below). As illustrated in FIG. 5, in operation, the heat transferred to the TE couples cools the working fluid, so that, for example, the fluid may enter somewhat above 600° C. so that the hot end of the first TE couple operates at 600° C., and the fluid cools so that the second couple operates at 400° C. and the third at 200° C. Thus, the hot side temperatures of the couples are progressively lower as the hot fluid cools by having given up thermal power to upstream TE couples.

If, for example, the couples are identical, the power output curves could be as shown in FIG. 5. If the couples were connected in series so that the same current, I, flowed through each, the contribution of each couple to total power output would be the sum of the powers corresponding to operating points A, B, and C. As depicted, maximum power is produced from the couple operating at 600° C., point A, but the output from the couple operating at point B (400° C.) is not optimal and the output from the couple operating at point C (200° C.) is actually slightly negative, so that it subtracts power output from the other two couples.

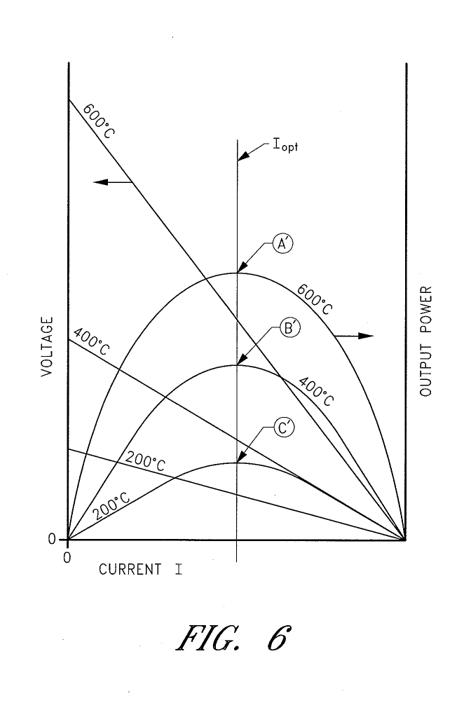

In some cases, it is desirable that each couple operate at the current that produces peak power output. To achieve this, several conditions can be controlled to obtain more optimal performance from the TE generator, more consistent with the graph depicted in FIG. 6. In FIG. 6, the system is designed to permit operation at higher efficiency, even though temperature or heat flux may change. For example, the form factor (shape) of the couples is advantageously adjustable (as described in U.S. Pat. No. 6,672,076, entitled Efficiency Thermoelectrics Utilizing Convective Heat Flow and U.S. Pat. No. 6,539,725 entitled Efficiency Thermoelectric Utilizing Thermal Isolation, or in any other suitable manner) or sized so that the power produced from each couple operates at the point of peak power or peak efficiency. For example, if power output is to be maximized, the couples could be sized, as is well known to those skilled in the art [see Angrist, “Direct Energy Conversion” Third Edition, chapter four, for example], to have the characteristics shown in FIG. 6, for a TE module with couples operating at 600° C., 400° C., and 200° C. In this case, the TE couples, heat transfer characteristics and power output of the module have been maximized by operating all stages substantially at the current that substantially maximizes power output, designated A′, B′ and C′ in FIG. 6. For operation at peak efficiency, or other operating conditions, other design criteria could be used to achieve other desired performance characteristics.

FIG. 7 is a schematic of a simple TE power generator 700. The TE power generator 700 in this illustration has three pairs of TE elements 709 electrically connected in series by hot side shunts 706, 707, 708, and cold side shunts 710. Hot side fluid 701 enters hot side duct 716 (e.g., from the left at an input port) and is in good thermal contact with heat exchangers 703, 704 and 705 and exits the hot side duct 716 (e.g., to the right at an output port). The heat exchangers 703, 704 and 705 are in good thermal contact with the hot side shunts 706, 707 and 708. Cold side fluid 712 enters cold side duct 711 (e.g., from the right at an input port) and exits the cold side duct 711 (e.g., to the left at an output port). The TE generator 700 has electrical connections 714 and 715 to deliver power to an external load (not shown).

In operation, hot side fluid 701 enters hot side duct 716 and transfers heat to heat exchanger 703. The hot side fluid 701, cooled by giving up some of its heat content to the heat exchanger 703, then transfers an additional amount of its heat to heat exchanger 704, and then some additional heat to heat exchanger 705. The hot side fluid 701 then exits the hot side duct 716 (e.g., to the right at an output port). Heat is transferred from hot side heat exchangers 703, 704 and 705 to hot side shunts 706, 707, 708, then to the TE elements 709. The TE elements 709 are also in good thermal communication with cold side shunts 710 which are in good thermal communication with the cold side duct 711, which is in good theraml communication with the cold side fluid 712. Due to the differing temperatures of the hot side fluid 701 and the cold side fluid 712, the TE elements 709 experience a temperature differential by which electrical power is produced by the TE elements 709 and extracted through electrical connections 714 and 715.

The TE power generator 700 depicted in FIG. 7 for the operating characteristics shown schematically in FIG. 6, will only have peak temperatures of 600° C., 400° C., and 200° C. on the hot side under specific conditions. For example, if the working fluid conditions that achieve the performance shown in FIG. 6 are changed by decreasing the fluid mass flow, and increasing inlet temperature a corresponding appropriate amount, the first TE couple will still be at 600° C., but the temperatures of the other two couples will decrease. A condition could be produced such as that shown schematically in FIG. 8, in which the operating points A″, B″ and C″ do not yield a TE module with optimal performance when the TE elements are connected as shown in FIG. 7. The resulting imbalance in operating currents, similar to that of FIG. 5, and described above, would reduce power output undesirably.

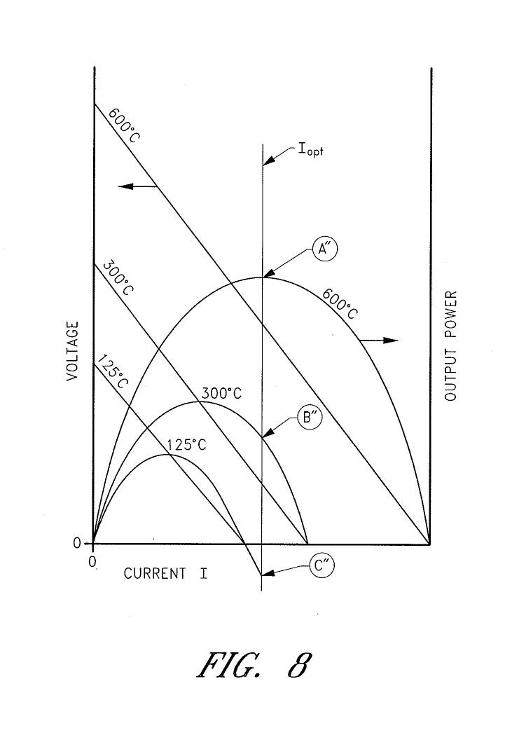

An advantageous configuration of a TE power generator system 900, for example for power generation from waste heat from an engine, is depicted in schematic form in FIG. 9. The hot exhaust 903 from the engine passes through a hot side duct 901 and exits as cool exhaust 904. A hot side heat exchanger 902 is in good thermal communications with the hot side duct 901, and thereby, in thermal communication with the hot exhaust 903. In this embodiment, a pump 909 pumps hot side working fluid 906. A TE generator 919, consisting of TE modules, is in good thermal communication with the hot side working fluid 906, 905, 907. A cold side coolant 911 is contained in a coolant duct 910 and passes in good thermal contact with the TE generator 919, engine 913, and radiator, 914. A pump 915 pumps a cold-side working fluid 911 through the cold side ducts 910. A valve 912 controls flow direction of the cold-side working fluid 911. Various communication channels, power sources and signal transmitters, are designated collectively as other devices 918. A controller 916 is connected to the other devices 918, to the pump 915, and to at least one sensor, or a plurality of sensors (not shown), to the TE module 919, and to other parts of the vehicle via harnesses or buses 916, 917.

In operation, the hot exhaust 903 passing through the hot side duct 901 heats a hot side working fluid 906, which passes through the hot side working fluid conduit 902. This hot-side working fluid 906 provides heat for the hot side of the TE generator 919. The TE generator 919 is operated generally as described in the description of FIG. 7 to produce electrical power. The pump 915 pumps cold side working fluid (a coolant) 911, to remove unused (waste) heat from the TE generator 919. The waste heat absorbed in cold-side coolant 911 is directed by a valve V₁ 912. The valve 912 can be used to direct the cold-side coolant for the most beneficial use depending on current operating conditions. For example, the valve V₁ 912 may direct cold side working fluid 910 either to the engine, if it is cold, such as during startup, or to a radiator 914 to eliminate waste heat. The controller 916 utilizes sources of information (for example from sensors, some of which are presently available on automobiles), such as fuel and air mass flow rate, pressures, exhaust temperatures, engine RPM, and all other available relevant information to adjust the flow from the pumps 909, 915, and the controls within the TE generator 919 to achieve the desired output from the waste-heat recovery system 900.

For certain embodiments disclosed herein, the hot side fluid (906 in this case) may be steam, NaK, HeXe mixture, pressurized air, high boiling point oil, or any other advantageous fluid. Further, the hot side fluid 906 may be a multi-phase system, as an example, nanoparticles dispersed in ethylene glycol/water mixture, a phase change multi-phase system, or any other advantageous material system. Further, by utilizing direct thermal connection, and by eliminating unneeded components, solid material systems, including heat pipes, could replace the fluid-based systems described above.

For certain embodiments disclosed herein, the cold-side loop may also employ any heat elimination mechanism, such as a finned aluminum tubular cores, evaporative cooling towers, impingement liquid coolers, heat pipes, vehicle engine coolants, water, air, or any other advantageous moving or stationary heat sinking apparatus.

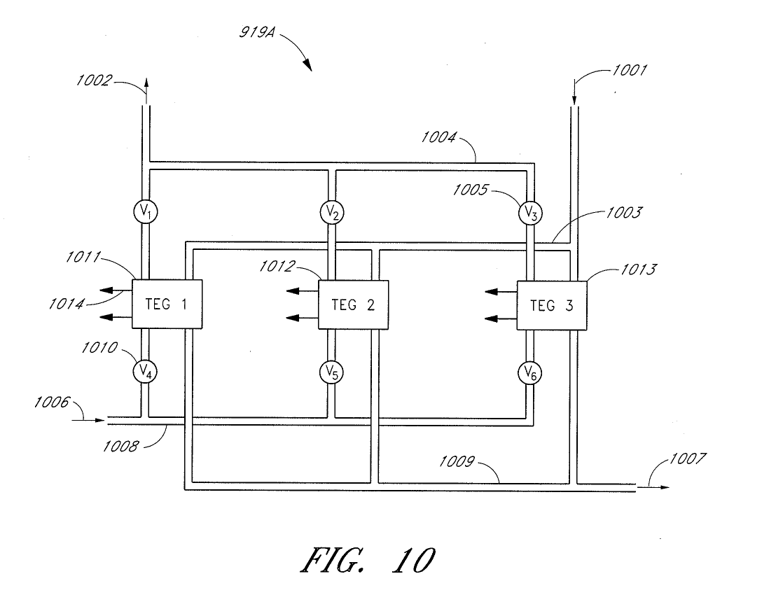

The controller 916 controls the TE generator 919, hot and cold side heat exchangers, based on sensors and other inputs. The controller 916 monitors and controls the functions to, at least in part, produce, control, and adjust or modify electrical power production. Examples of a TE generator 919 are provided in more detail in the discussions of FIGS. 10 and 11. Again, such controller operation described here is not limited to this particular embodiment.

The TE controller 916 is in communication with, and/or monitors operating conditions in any or all of the following components: mechanisms for devices measuring, monitoring, producing, or controlling the hot exhaust; components within the TE generator 919; devices within the cold side loop such as valves, pumps, pressure sensors, flow, temperature sensors; and/or any other input or output device advantageous to power generation. An advantageous function of the controller is to vary the operation of the hot side and/or cold size fluid flows so as to advantageously change the electrical output of the TE generator. For example, the controller could control, change and monitor pump speed, operate valves, govern the amount of thermal energy storage or usage and vary TE generator output voltage or current, as well as perform other functions such as adjust hot exhaust production and/or any other advantageous changes to operation. As an example of control characteristics, if the system is utilized for waste heat recovery in a vehicle, and the cold side fluid is engine coolant, a 2-way valve can be controlled by the controller or any other control mechanism to advantageously direct the flow.

Gasoline engines perform more efficiently once they warm up. Cold-side loop flow warmed by removing waste heat from the TE generator 919 can speed up the heating of the engine, if properly directed. Alternatively, the heated cold-side coolant 910 could pass through a heat exchanger to heat passenger air and then return to the TE generator inlet or be directed to the engine, to help heat it. If the engine is hot, the cold-side coolant could be directed to a radiator or any other advantageous heat sink, bypassing the engine, and then returning to the TE generator inlet.

FIG. 10 depicts one possible embodiment for a TE generator 919A as an example of the TE generator 919 of FIG. 9. The TE system 919A has three TE generators, TEG1 1011, TEG2 1012 and TEG3 1013. In this embodiment, each of the TE generators 1011, 1012, 1013 are in thermal communication with a hot-side duct 1003, 1004. The hot side ducts 1003, 1004 have hot side fluid 1001, 1002. Cold-side ducting 1008, 1009, similarly, contains a cold side working fluid 1006, 1007. Hot-side valves V1, V2 and V3 1005 control the flow of hot side fluid 1001, 1002 to the TE generators TEG1 1011, TEG2 1012, and TEG3 1013, respectively. Similarly, cold side valves V4, V5 and V6 1010 control the flow of cold side fluid flow to the TE generators TEG1 1011, TEG2 1012, and TEG3 1013, respectively. Wire harnesses 1014 transmit electrical power produced by the TE generators TEG1 1011, TEG2 1012, and TEG3 1013, to other parts of the vehicle. Sources of information and control mechanisms such as fuel and air mass flow rate, pressures, exhaust temperatures, engine RPM, and all other available relevant information to adjust the operation of TE generator 919A, and the connections to pumps, valves 1005, 1006, and all other mechanisms are not shown.

In operation, flow of the hot side fluid 1001 provides thermal power to the TE generators TEG1 1011, TEG2 1012, and TEG3 1013, can be operated by suitably functioning valves V₁-V₆ 1005, 1006. By way of example, at a low thermal power input, valves V₁ and V₄, 1005, 1006 would open to heat the hot side and cool the cold side of one TE generator TEG1 1011. The other valves V₂-V₆ would remain in a state to prevent heating of the second TE generator TEG2 1012, and the third TE generator TEG3 1013. The pump 909 (shown in FIG. 9) would be adjusted to provide flow of hot side fluid 901 that maximizes power output from the first TE generator TEG1 1011. Similarly, the pump 915 (shown in FIG. 9), would be adjusted to provide the flow of hot side fluid 1001 that maximizes power output from the first TE generator TEG1 1011. If the available thermal power increases, valves V₂ and V₅ 1005, 1006 could be actuated to engage the second TE module TEG2 1012. The pump 909 (see FIG. 9) could be adjusted by the controller 916 to maximize power output from the first TE generator TEG1 1011 and the second TE generator TEG2 1012.

Alternatively, the first TE generator TEG, 1011 could be shut off by shutting off valves V₁ and V₄ 1005, 1006 (or just Valve V₁) if performance were further improved by doing so. Similarly, at higher thermal powers, TEG3, 1013, could be engaged either alone or in combination with TEG1, 1011, and/or TEG2, 1012. The control, sensors, valves, and pump described in FIG. 8 adjust operation.

FIG. 10 depicts just one possible embodiment of a TE generator 919. Other variations are possible. For instance, the system could consist of at least two, but any number of TE modules that can operate at least partially independent of each other. Advantageously each such TE module has a different capacity, as depicted by being different sizes in FIG. 10. By having TE modules of different capacity, and the ability to switch thermal power to activate or remove each TE module independently from operation, allows the controller 916 to adapt to substantially changing operational conditions.

FIG. 11 depicts another alternative of a TE system 919B for the TE generator 919 (FIG. 9). Again, this TE system 919B is designed to improve output efficiency from a varying heat source such as automotive exhaust. As shown, the TE system 1100 has three TE generators TEG1 1104, TEG2 1105 and TEG3 1106, in good thermal communication with a hot side heat source 1101. In the example of an automobile, this could be exhaust or another hot fluid. The hot side heat source 1101 preferably flows through a hot side duct 1102. In this embodiment, the hot side heat duct is divided into three hot side ducts 1111, 1112, 1113, each designed to carry some portion of the heat source 1101. In FIG. 11, the hot side heat source 1101 is in thermal communication with the TE generators TEG1 1104, TEG2 1105, and TEG3 1106 through the three hot side ducts 1111, 1112 and 1113. An output valve 1108 controls hot side fluid 1103 as the output. The cold side fluid 1109, 1110 in cold side ducts 1114, 1115 cools the TE generators TEG1 1104, TEG2 1105, and TEG3 1106. The flow of the cold-side fluid 1109 is controlled by the valves V1, V2 and V3 1107.

Operation of TE system 919B follows the principles described for FIGS. 9 and 10, but the hot side working fluid 906 is omitted and thermal power is transferred without a separate hot side working fluid loop. For example, in this embodiment, the exhaust flows through the conduit 1101, and no separate working fluid is provided. In this embodiment, the TE generators TEG1 1104, TEG2 1105, and TEG3 1106 are coupled through hot side heat exchangers (not shown) in thermal communication with the hot exhaust such as by direct coupling, insertion into the exhaust stream, heat pipes or any other suitable mechanism. In FIG. 11, the three TE generators TEG1 1104, TEG2 1105, and TEG3 1106, preferably of different capacities, are depicted, as in FIG. 10. Valves V₁, V₂, and V₃, 1107, and other devices, pumps, sensors, and other mechanisms, not shown, control cold-side working fluid 1110 flow. In operation, the valve 1108 controls exhaust flow to the TE modules TEG1 1104, TEG2 1105, and TEG3 1106. Various TE generators TEG1 1104, TEG2 1105, and TEG3 1106, engage, dependant on input conditions the desired electrical output. Exhaust valve V₄ 1108 could be one or more valves.

As mentioned above, although three TE generators are shown, at least two or more in any number could be used. Each TE generator could be multiple modules operating between different hot sides and/or cold side temperatures.

Further, in some embodiments, exhaust flow could be directed through any or all of the hot side pathways to vary performance not associated with electrical production, for example, to adjust exhaust back pressure, improve combustion efficiency, adjust emissions, or any other reason. In addition, the construction of the TE modules to be devised so that in the case of waste heat recovery from a fluid stream the configuration could adjust noise or combustion characteristics to incorporate all or part of the features of mufflers, catalytic converters, particulate capture or treatment, or any other desirable integration with a device that is useful in overall system operation.

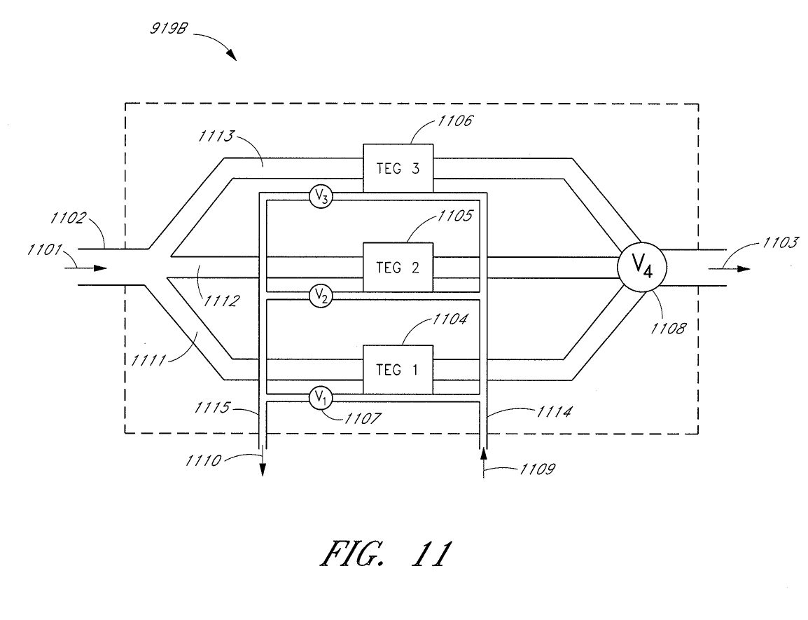

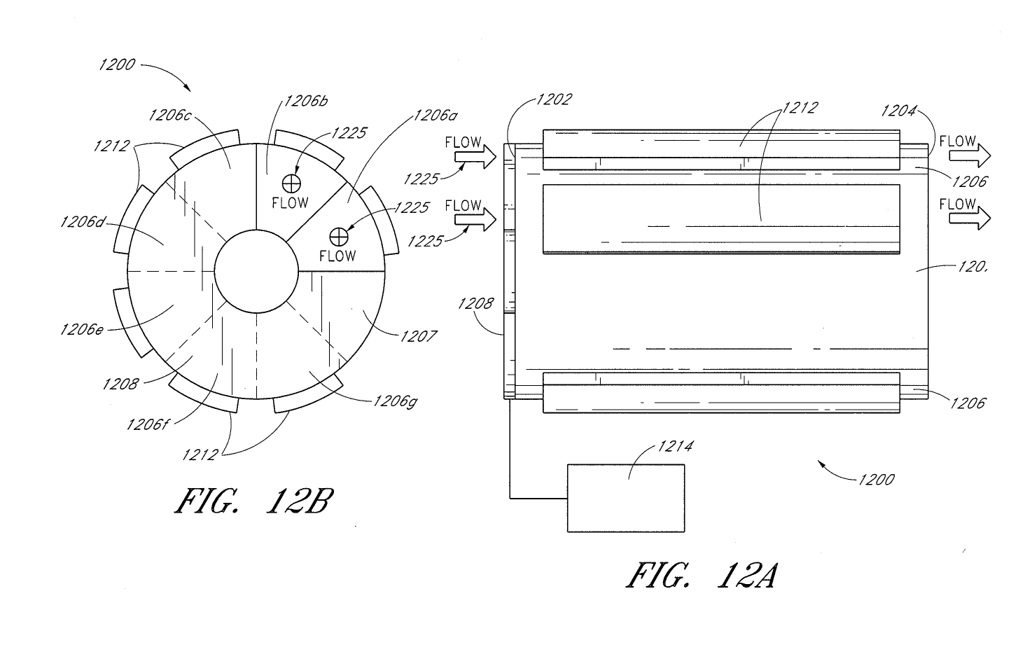

FIGS. 12A, 12B, 13A, 13B, and 14 schematically illustrate example thermoelectric (“TE”) generators 1200 in accordance with certain embodiments described herein. In certain embodiments, such as the example depicted (from alternative viewpoints) in FIGS. 12A and 12B, a TE generator 1200 may comprise an input portion 1202, an output portion 1204, a plurality of elongate TE segments 1206, and at least one movable element 1208. The input portion 1202 may be configured to allow a working fluid 1210 to flow therethrough. The output portion 1204 may be configured to allow the working fluid 1210 to flow therethrough. The plurality of elongate TE segments 1206 may be substantially parallel to one another, and at least one of the segments 1206 may comprise at least one TE module 1212. Each TE segment 1206 may be configurable to allow the working fluid 1210 to flow therethrough from the input portion 1202 to the output portion 1204. The at least one movable element 1208 may be positionable to allow flow of the working fluid 1210 through at least a first TE segment of the plurality of TE segments 1206 and to inhibit flow of the working fluid 1210 through at least a second TE segment of the plurality of TE segments 1206.

The input portion 1202 and the output portion 1204 of the TE generator 1200 allow working fluid 1210 to pass therethrough, at least when not blocked or inhibited by the one or more movable elements 1208. Arrows 1225 in FIGS. 12A and 12B generally indicate the direction of the flow of the working fluid 1210 through the TE segments 1206. Thus, when flow is not completely inhibited by the movable element 1208, the working fluid 1210 flows generally through the input portion 1202, then through the plurality of elongate TE segments 1206, and then through the output portion 1204. As the working fluid 1210 flows between the input portion 1202 and the output portion 1204, there may be other intervening components of the TE generator 1200 through which the working fluid 1210 flows in addition to the TE segments 1206. The input portion 1202 and the output portion 1204 may comprise one or more pipes, tubes, vents, ducts, conduits, or the like, and, generally, many be configured in a variety of ways that allow the working fluid 1210 to pass. While the input portion 1202 and the output portion 1204 allow the working fluid 1210 to pass therethrough, flow, in certain embodiments, is not necessarily uninterrupted or unimpeded. Thus, for example, in some embodiments, the input portion 1202 and the output portion 1204 may comprise a grill or mesh or some sort of variegated surface, whereas in other embodiments, the input portion 1202 and the output portions 1204 may simply provide a passage for the working fluid 1210 to flow. In some embodiments, the input portion 1202 and the output portion 1204 may be fluidically coupled to a recirculation system such that the working fluid 1210 flowing out of the output portion 1204 eventually returns to the input portion 1202. In some embodiments, the input portion 1202 and the output portion 1204 of the TE generator 1200 may be fluidically connected in parallel or in series with the input portion 1202 and the output portion 1204 of another TE generator 1200. In some embodiments, the fluidic connections between the input portions 1202 and output portions 1204 of multiple TE generators 1200 may comprise a combination of serial and parallel fluidic connections.

The plurality of TE segments 1206 may have a variety of cross-sectional shapes, and may be arranged in a variety of configurations relative to one another. For example, in some embodiments, such as the embodiment schematically illustrated in FIGS. 12A and 12B (from alternative viewpoints), the plurality of TE segments 1206 may have a generally circular cross-section in a plane perpendicular to the TE segments 1206. In addition, in certain such embodiments, each TE segment 1206 may have a generally trapezoidal cross-section in a plane perpendicular to the plurality of TE segments 1206, as schematically illustrated in FIG. 12B. However, the individual TE segments 1206 may also have other cross-sectional shapes including, but not limited to, generally triangular, pie-piece shaped, and generally circularly segmented. While the TE segments 1206 illustrated in FIGS. 12A and 12B share a common side with a neighboring segment 1206, in certain other embodiments, the segments 1206 are spaced from one another.

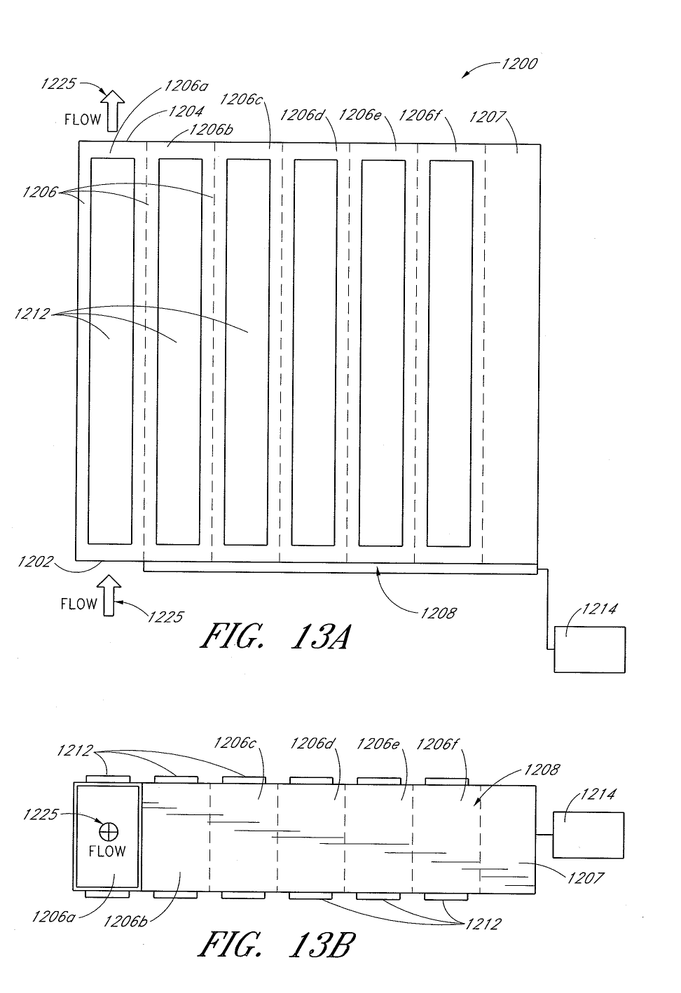

FIGS. 13A and 13B schematically illustrate (from alternative viewpoints) an example TE generator 1200 where the TE segments 1206 are generally planar with one another. In certain such embodiments, each TE segment 1206 may have a generally rectangular cross-section in a plane perpendicular to the plurality of TE segments 1206, as schematically illustrated in FIG. 13B. However, the individual TE segments 1206 may also have other cross-sectional shapes including, but not limited to, generally square, generally trapezoidal, and generally triangular. While the TE segments 1206 schematically illustrated in FIGS. 13A and B share a common side with a neighboring TE segment 1206, in certain other embodiments, the TE segments 1206 are spaced from one another.

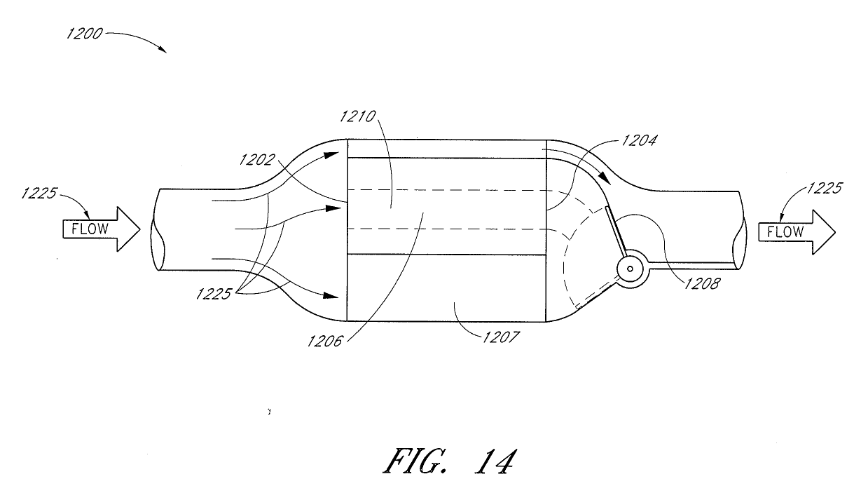

FIG. 14 schematically illustrates another example TE generator 1200 wherein the TE segments 1206 are generally planar with one another. In this example, each TE segment 1206 comprises a linear region and a curved region. Generally, in certain embodiments, the TE generator 1200 may comprise linear and/or curved TE segments 1206, or may comprise TE segments 1206 that have both linear and curved regions as FIG. 14 schematically illustrates. The cross-sectional shape of each TE segment 1206 is not shown in FIG. 14, but as described above, many cross-sectional shapes are possible, including, but not limited to, generally square, generally trapezoidal, and generally triangular. While the TE segments 1206 schematically illustrated in FIG. 14 share a common side with a neighboring TE segment 1206, in certain other embodiments, the TE segments 1206 are spaced from one another.

At least one of the TE segments 1206 comprises at least one TE module 1212; however, in some embodiments, each of multiple TE segments 1206 comprises one or more TE modules 1212. For instance, the example TE generator 1200 illustrated in FIGS. 12A and 12B comprises seven TE segments 1206, and a conduit 1207 lacking a TE module 1212. In certain such embodiments, the conduit 1207 lacking a TE module 1212 effectively serves as a bypass since working fluid 1210 passing through this conduit 1207 will not be in thermal communication with any TE module 1212. Thus, the conduit 1207 serving as a bypass allows some of the working fluid 1210 to pass through the plurality of TE segments 1206 without putting a thermal load on any of the TE modules 1212. In this way, the conduit 1207 serving as a bypass allows the TE generator 1200 to handle a flow rate of working fluid 1210 that might otherwise overload the combined thermal capacity of the TE modules 1212 in the absence of a bypass.

Another possible arrangement of TE segments 1206 and modules 1212 is schematically illustrated in FIGS. 13A and 13B (from alternative viewpoints). FIGS. 13A and 13B display an embodiment of a TE generator 1200 comprising seven TE segments 1206, six of the seven TE segments 1206 comprising two TE modules 1212 mounted on opposite sides of each TE segment 1206. Again, the TE segment 1206 lacking a TE module 1212 effectively serves as a bypass as described above.

Each TE module 1212 comprises one or more TE elements, and may optionally comprise one or more heat exchangers for promoting the transfer of thermal energy between the TE module 1212 and the working fluid 1210. The one or more TE elements are electronic devices, oftentimes solid state electronic devices, capable of generating electrical power when a thermal gradient is applied across at least a portion of the electronic device. The TE modules 1212 can embody a wide variety of designs, such as described in U.S. Pat. Nos. 6,539,725, 6,625,990, and 6,672,076, each of which is incorporated in its entirety by reference herein. However, any functioning TE element having the ability to convert thermal energy to electric energy can be used to construct TE modules 1212 compatible with certain embodiments described herein.

If there are multiple TE elements within a particular TE module 1212, a variety of electronic connections between the TE elements are possible. For example, the TE elements can be electrically connected together in series, electrically connected together in parallel, or electrically connected with a combination of series and parallel connections. In some embodiments, TE modules 1212 of varying thermal capacity may be created, for example, by connecting different numbers of an identical type of TE element together in series.

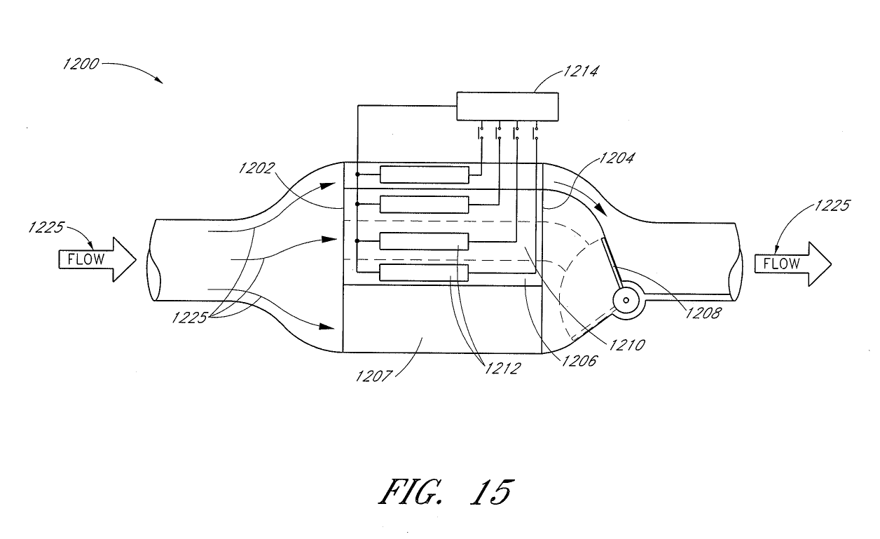

The TE modules 1212 of a TE segment 1206 may be electrically connected in a variety of configurations. For example, in some embodiments the TE modules 1212 may be electrically connected in series, they may be electrically connected in parallel, or they may be electrically connected by a combination of series and parallel connections. In certain embodiments, the TE generator 1200 comprises an array of TE modules 1212 electrically connected in parallel as illustrated in FIG. 15 (which will be discussed more fully below).

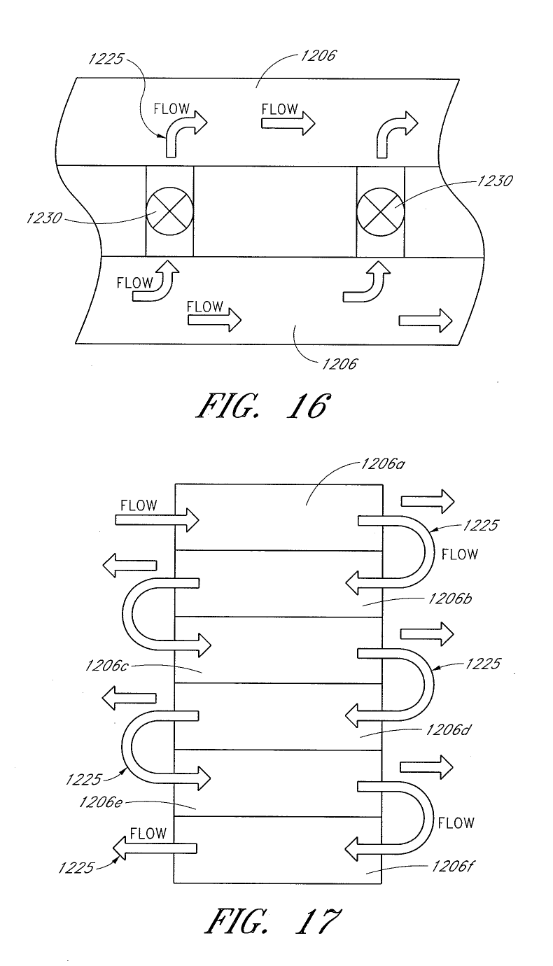

In some embodiments, the plurality of TE segments 1206, or a subset of the plurality of TE segments 1206, may be in fluidic communication with one another. The fluidic connections between TE segments 1206 may be such that two or more TE segments 1206 are in parallel fluidic communication with one another, as is the case in the examples schematically illustrated in FIGS. 12A, 12B, 13A, 13B, and 14. However, two or more TE segments 1206 may also be fluidically connected in series, or by a combination of series and parallel fluid connections. FIG. 16 and 17 schematically illustrate two example configurations for fluidically connecting TE segments 1206, though other configurations for connecting the TE segments 1206 are also compatible with certain embodiments described herein. In both FIGS. 16 and 17, the arrows 1225 indicate the direction of flow. In FIG. 16, there are two fluidically parallel flow paths for the working fluid 1210 through the TE segments 1206 when the valves 1230 are closed. When either of the valves 1230 open, serial flow paths are created along with the parallel flow paths. In FIG. 17, the TE segments 1206 are connected so that at least a portion of the working fluid 1210 flows serially through each TE segment 1206 by flowing through each consecutive TE segment 1206. In addition, at least a portion of the working fluid 1210 flows in parallel through some of the TE segments 1206 (e.g., 1206a, 1206c, 1206e) in a first direction and at least a portion of the working fluid flows in parallel through some of the TE segments 1206 (e.g., 1206b, 1206d, 1206f) in a second direction opposite to the first direction.

The at least one movable element 1208 may be positioned or mounted relative to the plurality of TE segments 1206 to move in a variety of ways as schematically illustrated by FIGS. 12A, 12B, 13A, 13B, and 14. For example, in some embodiments, such as the example schematically illustrated in FIGS. 12A and 12B, at least one movable element 1208 may be configured to rotate about an axis of rotation which is generally parallel to the TE segments 1206. For example, the at least one movable element 1208 can comprise one or more holes through which the working fluid 1210 can flow, and by rotating the at least one movable element, the holes can be aligned with selected TE segments 1206 while blocking flow through the other TE segments 1206. This is illustrated in FIGS. 12A and 12B, wherein the movable element 1208 is positioned such that the movable element 1208 substantially blocks flow of the working fluid 1210 through TE segments 1206c-1206g and the conduit 1207, while the working fluid 1210 is allowed to flow relatively unimpeded through TE segments 1206a and 1206b. In other embodiments, such as the example schematically illustrated in FIG. 14, at least one movable element 1208 may be configured to rotate about an axis of rotation which is generally perpendicular to the TE segments 1206. For example, the at least one movable element 1208 can comprise a baffle which can be rotated to allow flow through selected TE segments 1206 and to block flow through the other TE segments 1206. In still other embodiments, such as the example schematically illustrated in FIGS. 13A and 13B; at least one movable element 1208 may be configured to move substantially linearly along a direction generally perpendicular to the TE segments 1206. For example, the at least one movable element 1208 can be translated to allow flow through selected TE segments 1206 and to block flow through the other TE segments 1206. This is illustrated in FIGS. 13A and 13B, wherein the movable element 1208 is positioned such that the movable element 1208 substantially blocks flow of the working fluid 1210 through TE segments 1206b-1206f and the conduit 1207, while the working fluid 1210 is allowed to flow relatively unimpeded through TE segment 1206a. However, the movable element 1208 need not be restricted to exclusively rotational motion or exclusively linear motion. Therefore, in some embodiments, the movable element 1208 may move through a combination of rotational motion and linear motion. Furthermore, the rotational motion may be about an axis of rotation that is neither perpendicular nor parallel to the TE segments 1206.

In some embodiments, the at least one movable element 1208 is positionable to allow flow of the working fluid 1210 through at least a first TE segment 1206 of the plurality of TE segments 1206 and to inhibit flow of the working fluid 1210 through at least a second TE segment 1206 of the plurality of TE segments 1206. In some embodiments, the at least one movable element 1208 is positionable in multiple positions comprising a first position, a second position, and a third position. In the first position, flow of the working fluid 1210 is allowed through the first and second TE segments 1206 simultaneously. In the second position, flow of the working fluid 1210 is allowed through the first TE segment 1206, but is simultaneously inhibited through the second TE segment 1206. In the third position, flow is simultaneously inhibited through both the first and second TE segments 1206.

In some embodiments, such as the examples schematically illustrated in FIGS. 12 and 14, the at least one movable element 1208 moves between at least two of the multiple positions (e.g. the first, second, and third positions) by a substantially rotational displacement about an axis of rotation. As illustrated by the example in FIGS. 12A and 12B, the axis of rotation can be substantially parallel to the TE segments 1206, or, as illustrated in FIG. 14, the axis of rotation can be substantially perpendicular to the TE segments 1206. However, other embodiments may comprise one or more movable elements 1208 which rotate about an axis of rotation that is neither substantially parallel nor substantially perpendicular to the TE segments 1206. In other embodiments, such as the example schematically illustrated in FIGS. 13A and 13B, at least one movable element 1208 moves between at least two of the multiple positions (e.g. the first, second, and third positions) by a substantially linear displacement. In certain embodiments, one or more of the movable elements 1208 corresponds to each TE segment 1206. For example, each TE segment 1206 can comprise a movable element 1208 which selectively allows or inhibits flow through the TE segment 1206. By separately actuating the movable elements 1208, the working fluid 1210 can be controlled to flow through one or more selected TE segments 1206 and to not flow through other TE segments 1206.

In certain embodiments, the at least one movable element 1208 may inhibit flow of the working fluid 1210 through a TE segment 1206 by at least partially blocking an input end of a TE segment 1206. For example, the TE generators 1200 illustrated schematically in FIGS. 12A and 12B, and FIGS. 13A and 13B utilize a movable element 1208 to block the input end of one or more TE segments 1206. Alternatively, the at least one movable element 1208 may inhibit flow of the working fluid through a TE segment 1206 by at least partially blocking an output end of the TE segment 1206. For instance, the example TE generator 1200 illustrated schematically in FIG. 14 utilizes a movable element 1208 to block the output end of one or more TE segments 1206. In certain embodiments, the at least one movable element 1208 comprises one or more movable elements 1208 corresponding to each TE segment 1206, and these movable elements 1208 can be positioned to selectively block the input end, or the output end of the respective TE segments 1206. In certain such embodiments, at least some of the movable elements 1208 selectively block the input end of their respective TE segments 1206 and at least some of the movable elements 1208 selectively block the output end of their respective TE segments 1206.

In some embodiments, selecting the position of the at least one movable element 1208 among the multiple positions modifies the delivery of thermal power from the working fluid 1210 to the first and second TE segments 1206. In certain embodiments, the position of the movable element 1208 may be selected to modify the rate of removal of waste heat from a first TE segment 1206 or from a second TE segment 1206. The preceding description encompasses embodiments having more than two TE segments 1206 and also having one or more movable elements 1208 which are positionable in more than three positions—thereby providing a mechanism to selectively allow and inhibit flow through more than two TE segments 1206.

The working fluid 1210 supplies thermal energy to the TE modules 1212 (and to the TE elements of the TE modules 1212) by flowing from the input portion 1202, through the TE segments 1206, and to the output portion 1204. The working fluid 1210 can comprise any material capable of transporting thermal energy and transferring it to the TE modules 1212 as the working fluid 1210 passes through the TE segments 1206. For example, in some embodiments, the working fluid 1210 can comprise steam, NaK, He and Xe gas, pressurized air, or high boiling point oil. In some embodiments the working fluid 1210 can be a multi-phase system comprising, for example, nanoparticles dispersed in a mixture of water and ethylene glycol, or can comprise a phase change multi-phase system. In embodiments wherein one or more of the TE modules 1212 comprise one or more heat exchangers, the heat exchangers generally facilitate transfer of thermal energy from the working fluid 1210 to the TE modules 1212 and TE elements. Heat transfer may be facilitated, for example, by the presence of one or more heat transfer features (e.g., fins, pins, or turbulators), integral to the heat exchanger, which extend into the flow path of the working fluid 1210 as it passes through the TE segments 1206. In certain embodiments, the heat exchangers and the TE modules 1212 are configured to have thermal isolation in the direction of flow as described in U.S. Pat. No. 6,539,725, which is incorporated in its entirety by reference herein.

In certain embodiments, the TE generator 1200 may also comprise a controller 1214 configured to control the movement or position of the one or more movable elements 1208. For example, the one or more movable elements 1208 of certain embodiments are responsive to signals received from the controller 1214 by moving among multiple positions. In some embodiments, by controlling the movement or position of the one or more movable elements 1208, the controller 1214 can affect the flow of the working fluid 1210 through one or more TE segments 1206. Thus, in some embodiments, the controller 1214 can selectively modify the delivery of thermal power from the working fluid 1210 to one or more TE modules 1212. For example, the controller 1214 may effectively control which TE modules 1212 receive thermal power from the working fluid 1210, and which do not. In this way, the thermal capacity of the TE generator 1200 can be adjusted by the controller 1214 by modifying the number of TE modules 1212 which receive thermal power from the working fluid 1210 and by selecting the individual TE modules 1212 which receive thermal power from the working fluid 1210. In some embodiments, the adjustability is enhanced by having the TE generator 1200 comprise TE modules 1212 of differing sizes and/or thermal capacities.

In certain embodiments, the controller 1214 may function to selectively alter the electronic connections between the TE modules 1212. For example, the controller 1214 in FIG. 15 is configured such that it can selectively disconnect a particular TE module 1212 from the circuit such that the particular TE module 1212 is no longer electrically connected in parallel with the other TE modules 1212. Thus, in some embodiments, the thermal capacity of the TE generator 1200 can be adjusted by adjusting the electrical connectivity of the TE modules 1212. While the embodiment displayed in FIG. 15 is configured such that each TE module 1212 can be selectively connected and disconnected in parallel, in other embodiments the controller 1214 may only control the electrical connectivity of a subset of the total set of TE modules 1212. Furthermore, in other embodiments, the controller 1214 may selectively connect or disconnect TE modules 1212 in series, selectively connect or disconnect TE modules 1212 in parallel, or may simultaneously control series and parallel electrical connections between TE modules 1212.

In certain embodiments, the controller 1214 may control the movement or position of one or more movable elements 1208, and also control or alter the electronic connections between the TE modules 1212. Thus, in some embodiments, the delivery of thermal power by the working fluid 1210 to the TE modules 1212 and the electrical connectivity of the TE modules 1212 can be controlled in a coordinated fashion by the controller 1214 such that the controller 1214 can selectively decouple individual TE modules 1212 both thermally and electrically from the TE generator 1200.

Additionally, in some embodiments, a TE generator 1200 may comprise one or more sensors configured to measure one or more physical characteristics of the working fluid 1210 during the operation of the TE generator 1200. For example, one or more sensors coupled to the TE segments 1206 may measure the fluid pressure, temperature, or flow rate, or combination thereof, of the working fluid 1210 flowing through one or more of the TE segments 1206. For example, one or more of these physical characteristics can be measured within a portion of the TE generator 1200 (e.g., within a TE segment 1208). The measurements may be relayed to the controller 1214 by electrical connections between the sensors and the controller 1214 thereby allowing the controller 1214 to monitor the physical characteristics of the working fluid 1210. Thus, in some embodiments, the controller 1214 may be configured to receive one or more signals from the one or more sensors and to respond by transmitting one or more signals to the one or more movable elements 1208 for selectively coupling and decoupling (electrically and thermally) TE modules 1212 from the TE generator 1200 in response to the changing physical characteristics of the working fluid 1210. Certain such embodiments advantageously in order to increase the operating efficiency and/or total electrical power output of the TE generator 1200. Thus, the controller 1214 may alter the operation of the TE generator 1200 by controlling the position of one or more movable elements 1208 in response to the operational characteristics of the TE generator 1200 as determined by one or more pressure, temperature, or flow sensors.

In certain embodiments, such as the examples schematically illustrated in FIGS. 12A, 12B, 13A, 13B and 14, a TE generator 1200 may comprise a first TE segment 1206 having at least one TE module 1212, a second TE segment 1206 having at least one TE module 1212, and a movable element 1208 positionable in multiple positions. The multiple positions in which the movable element 1208 may be positioned may comprise a first position permitting flow of a working fluid 1210 through the first TE segment 1206 while simultaneously permitting flow of the working fluid 1210 through the second TE segment 1206, a second position inhibiting flow of the working fluid 1210 through the first TE segment 1206 while simultaneously permitting flow of the working fluid 1210 through the second TE segment 1206, and a third position inhibiting flow of the working fluid 1210 through the first TE segment 1206 while simultaneously inhibiting flow of the working fluid 1210 through the second TE segment 1206.

In certain embodiments, such as the examples schematically illustrated in FIGS. 12A, 12B, 13A, 13B and 14, the plurality of TE segments 1206 may further comprise a third TE segment 1206, and at least two of the TE segments 1206 may each comprise at least one TE module 1212. The movable element 1208 (although there may be more than one) may be positionable in multiple positions comprising a first position, a second position, a third position, and a fourth position. When in the first position, the movable element 1208 simultaneously permits flow of a working fluid 1210 through the first, second, and third TE segments 1206. When in the second position, the movable element 1208 inhibits flow of the working fluid 1210 through the first TE segment 1206 while simultaneously permitting flow of the working fluid through the second and third TE segments 1206. When in the third position, the movable element 1208 simultaneously inhibits flow of the working fluid 1210 through the first and second TE segments 1206 while simultaneously permitting flow of the working fluid 1210 through the third TE segment 1206. When in the fourth position, the movable element 1208 simultaneously inhibits flow of the working fluid 1210 through the first, second, and third TE segments 1206.

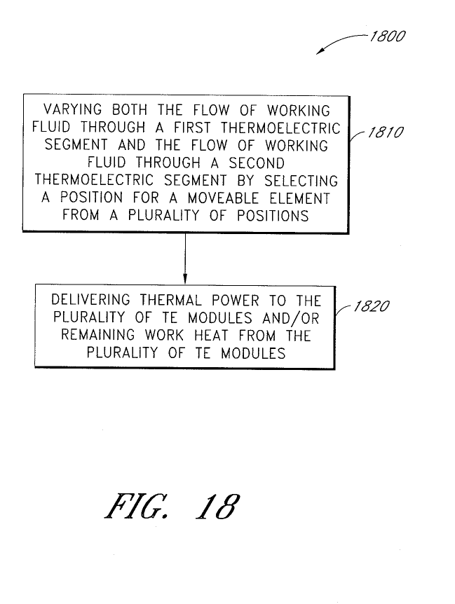

FIG. 18 is a flow diagram of an example method 1800 of operating a plurality of TE modules 1212 in accordance with certain embodiments described herein. While the method 1800 is described below with regard to the example TE generators 1200 of FIGS. 12A, 12B, 13A, 13B, and 14, other configurations can also be used. The method 1800 comprises varying both the flow of the working fluid 1210 through a first TE segment 1206 and the flow of the working fluid 1210 through a second TE segment 1206 (each TE segment comprising a TE module) by selecting a position for a movable element 1208 from a plurality of positions in an operational block 1810. The plurality of positions comprises: a first position permitting flow through the first TE segment while simultaneously permitting flow through the second TE segment; a second position inhibiting flow through the first TE segment while simultaneously permitting flow through the second TE segment; and a third position inhibiting flow through the first TE segment while simultaneously inhibiting flow through the second TE segment. In certain embodiments, the position of the movable element 1208 may be selected to increase efficiency, modify electrical power output characteristics, or both, of the plurality of TE modules 1212. Certain such methods further comprise delivering thermal power to the plurality of TE modules and/or removing waste heat from the plurality of TE modules in an operational block 1820. In certain embodiments, the method 1820 further comprises removing waste heat from the plurality of TE modules.

A thermal power source and delivery system may be thermally coupled to the TE generator 1200 to deliver thermal power to the TE generator 1200. Many different types of thermal power sources may be used with the TE generator 1200, and in principle, any device capable of providing deliverable thermal energy may be utilized. For example, the thermal power source may be an engine (e.g., an internal combustion engine) and the thermal power delivery system can comprise a coolant conduit or an exhaust conduit. The controller 1214 may be responsive to the operating conditions of the thermal power delivery system or thermal power source or both. For example, sensors configured to detect the operating conditions can be used to send signals to the controller to provide information regarding the operation of the thermal power delivery system or thermal power source or both. For instance, the sensors may be responsive to one or more pressures, flows, or temperatures within the thermal power delivery system, or within the thermal power delivery source, within both. Thus, the controller 1214 may alter the operation of the TE generator 1200 by controlling the position of one or more movable elements 1208 in response to the operational characteristics of the thermal power delivery system, the thermal power delivery source, or both, as determined by one or more pressure, temperature, or flow sensors. More generally, the controller 1214 may alter the operation of the TE generator 1200 through control of the movable elements 1208 in response to any combination of the operational characteristics of the TE generator 1200, the thermal power source, or the thermal power delivery system.

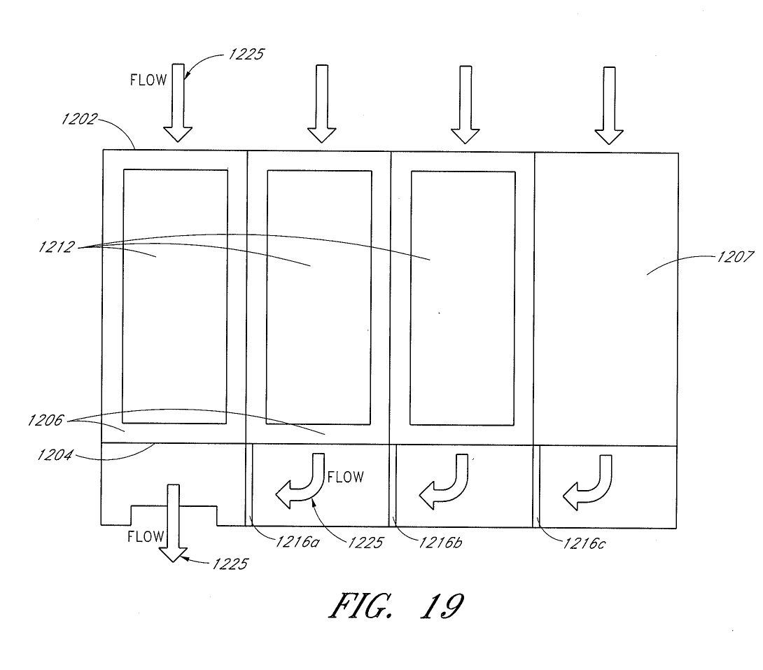

FIG. 19 schematically illustrates another example TE generator 1200 in accordance with certain embodiments described herein. In certain embodiments, such as the as schematically illustrated in FIG. 19, a TE generator 1200 may comprise a first TE segment 1206, a second TE segment 1206, and at least a first variable flow element 1216a. The first TE segment 1206 may comprise at least one TE module 1212, and the first TE segment 1206 may have a working fluid 1210 flowing therethrough with a fluid pressure. The second TE segment 1206 may comprise at least one TE module 1212, and the second TE segment 1206 may be configurable to allow the working fluid 1210 to flow therethrough. The first variable flow element 1216a may be movable upon application of the fluid pressure to the first variable flow element 1216a, the first variable flow element 1216a modifying a flow resistance of the second TE segment 1206 to flow of the working fluid 1210 therethrough.

In certain such embodiments, such as the example schematically illustrated in FIG. 19, the TE generator 1200 may further comprise a third TE segment 1206 configurable to allow the working fluid 1210 to flow therethrough, and the third TE segment 1206 may further comprise at least one TE module 1212. Additionally, in certain such embodiments, such as the example schematically illustrated in FIG. 19, the TE generator 1200 may further comprise a second variable flow element 1216b. Similar to the first variable flow element 1216a, the second variable flow element 1216b may be movable upon application of the fluid pressure to the second variable flow element 1216b, the second variable flow element 1216b modifying at least a flow resistance of the third TE segment 1206 to flow of the working fluid 1210 therethrough.

In the example embodiment schematically illustrated in FIG. 19, the TE segments 1206 (e.g., three) are positioned in a generally planar arrangement with respect to one another, and are in parallel fluidic communication with one another. In other configurations, the TE segments 1206 may be connected so that two, three, four or more TE segments 1206 are in series fluidic communication with one another. Combinations of series and parallel fluidic connections between the TE segments 1206 within a TE generator 1200 are also feasible.

In certain embodiments, the TE generator 1200 further comprises one or more conduits 1207 which do not comprise a TE module. In certain embodiments, the conduit 1207 is in parallel fluidically communication with the first TE segment 1206 and the second TE segment 1206. In certain embodiments, the conduit 1207 is in series fluidically communication with at least one of the first TE segment and the second TE segment. In certain embodiments, the TE generator 1200 may further comprising a second variable flow element 1216, and the second variable flow element 1216 (movable upon application of the fluid pressure to the second variable flow element) may modify at least a flow resistance of the conduit 1207 to flow of the working fluid 1210 therethrough. For example, the three TE segments 1206 of the example embodiment schematically illustrated in FIG. 19 are in selective parallel fluidically communication with the conduit 1207. In this example, the third variable flow element 1216c (movable upon application of the fluid pressure to the third variable flow element 1216c) may modify at least a flow resistance of the conduit 1207 to flow of the working fluid 1210 therethrough. Thus, the conduit 1207 effectively serves as a bypass by providing a flow path for the working fluid 1210 that avoids putting a thermal load on any TE module 1212. In this way, the conduit 1207 allows the TE generator 1200 to handle a flow rate of the working fluid 1210 that might otherwise overload the combined thermal capacity of the TE modules 1212 in the absence of a bypass.

The one or more variable flow elements 1216 affect flow of the working fluid 1210 through the TE segments 1206 by modifying a flow resistance of a TE segment 1206 to the flow of the working fluid 1210. A variable flow element may modify a flow resistance of a TE segment 1206 by at least partially blocking an output end of a TE segment 1206, as schematically illustrated in FIG. 19, or by at least partially blocking an input end of a TE segment 1206. In certain embodiments, the variable flow element 1216 may comprise a valve. For example, in certain such embodiments, the valve may be a flapper valve, which is generally a valve comprising a substantially planar blocking element and a hinge attached to the blocking element which allows the blocking element to move via a substantially rotational displacement about an axis defined by the hinge. With the flapper valve is in its closed position, the blocking element is oriented such that the plane of the blocking element is substantially perpendicular to the direction of fluid flow, thus reducing or eliminating the effective cross-sectional area through which fluid may flow. With the flapper valve in its open position, the blocking element is oriented such that the plane of the blocking element is not substantially perpendicular to the direction of fluid flow, thus opening a substantial cross-sectional area through which fluid may flow relatively unimpeded by the blocking element.

A variable flow element 1216 may be movable upon application of a fluid pressure to the variable flow element 1216. For example, the movable flow element 1216 can respond to the fluid pressure applied to the variable flow element 1216 to allow more flow through the corresponding TE segment 1206. Thus, through operation of one or more variable flow elements 1216, the flow resistance of a TE segment 1206 may depend on the fluid pressure within the TE segment 1206. The variation in flow resistance of the TE segment 1206 may result in a variation in flow rate of the working fluid 1210 through the TE segment 1206. Thus, since the working fluid 1210 carries thermal power, the amount of thermal power or heat flux delivered to a TE module 1212 of a TE segment 1206 may be modified by the movement of a variable flow element 1216. For example, movement of the first variable flow element 1216 can modify a delivery of thermal power or heat flux to the at least one TE module of the second TE segment 1206. Similarly, the rate of removal of waste heat from a TE module 1212 of a TE segment 1206 may be modified by the movement of a variable flow element 1216 effecting the flow resistance of the TE segment 1206. For example, movement of the first variable flow element 1216 can modify a rate of removal of waste heat from the at least one TE module 1212 of the second TE segment 1206.

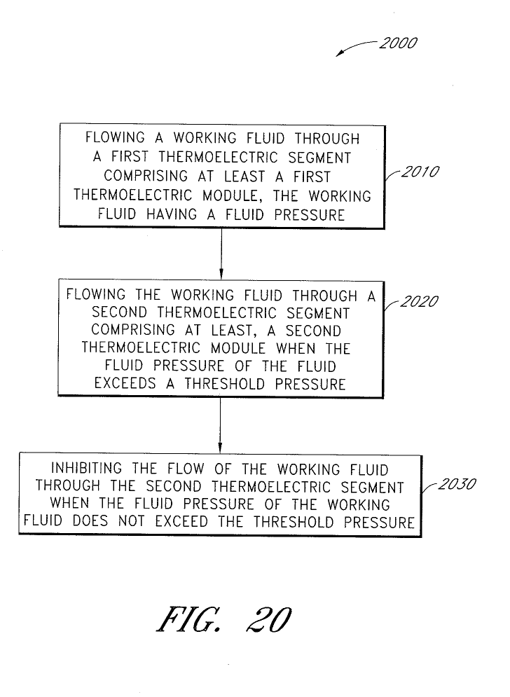

Through the use of a variable flow element 1216, a plurality of TE modules 1212 comprising a TE generator 1200 may be operated such that the flow of the working fluid 1210 through one or more TE segments 1206 may be adjusted according to operating conditions. One such operating condition is a fluid pressure of the working fluid 1210 within a TE segment 1206. FIG. 20 is a flow diagram of an example method 2000 of operating a plurality of TE modules 1212 in accordance with certain embodiments described herein. The method 2000 comprises flowing a working fluid 1210 through a first TE segment 1206 comprising at least a first TE module 1212, the working fluid 1210 having a fluid pressure in a first operational block 2010. The method 2000 further comprises flowing the working fluid 1210 through a second TE segment 1206 comprising at least a second TE module 1212 when the fluid pressure of the fluid exceeds a threshold pressure in a second operational block 2020. The method 2000 further comprises inhibiting the flow of the working fluid 1210 through the second TE segment 1206 when the fluid pressure of the working fluid 1210 does not exceed the threshold pressure in an operational block 2030. In certain embodiments, the threshold pressure may be selected to increase efficiency, modify electrical power output characteristics, or both, of the plurality of TE modules 1212. In certain embodiments, the method 2000 further comprises delivering thermal power to the plurality of TE modules 1212. In certain embodiments, the method 2000 further comprises removing waste heat from the plurality of TE modules 1212.

In certain embodiments described herein, the TE generator 1200 may also comprise variable flow elements 1216 which are responsive to the temperature of the working fluid, instead of (or in addition to) variable flow elements 1216 which are responsive to the fluid pressure of the working fluid. Thus, a TE generator 1200 may comprise a first TE segment 1206, a second TE segment 1206, and at least a first variable flow element 1216. The first TE segment 1206 may comprise at least one TE module 1212, and the first TE segment 1206 may have a working fluid 1210 flowing therethrough. The second TE segment 1206 may comprise at least one TE module 1212, and the second TE segment 1206 may be configurable to allow the working fluid 1210 to flow therethrough. The first variable flow element 1216 may be configured to move in response to a temperature of the first variable flow element 1216, the first variable flow element 1216 modifying a flow resistance of the second TE segment 1206 to flow of the working fluid 1210 therethrough.

The variable flow element 1216 may be responsive to the temperature of the working fluid 1210 within certain regions of the TE generator 1200. Thus, the movement of the temperature responsive variable flow element 1216 may be responsive to the temperature of the working fluid 1210. Movement of the variable flow element 1216 modifies the flow resistance of a TE segment 1206, so the flow rate of working fluid 1210 through a TE segment 1206 may depend on temperature. Since the working fluid 1210 carries thermal power, the amount of thermal power or heat flux delivered to a TE module 1212 of a TE segment 1206 may be modified by the movement of the variable flow element 1216 effecting the flow resistance of the TE segment 1206. Similarly, the rate of removal of waste heat from a TE module 1212 of a TE segment 1206 may be modified by the movement of a variable flow element 1216 effecting the flow resistance of the TE segment 1206.

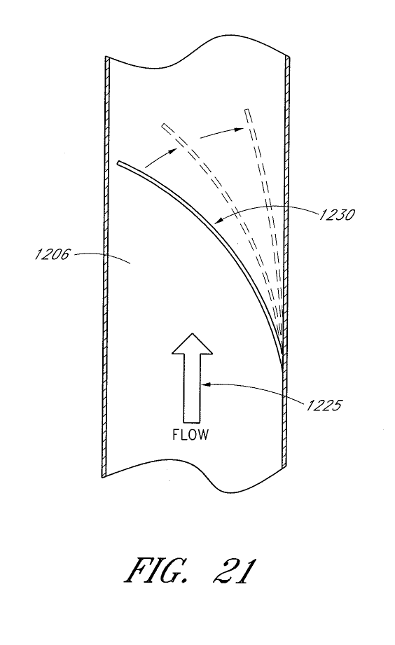

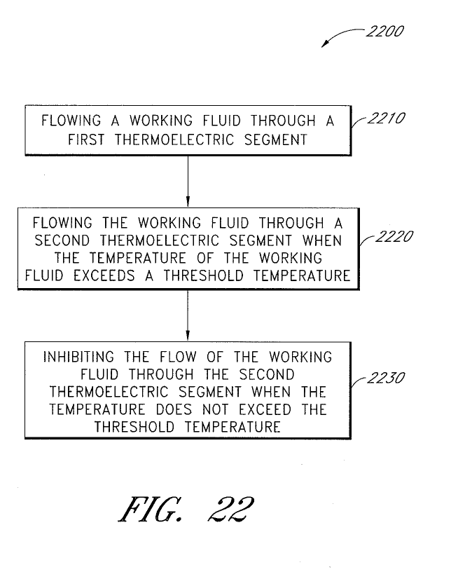

A suitable temperature responsive variable flow element 1216 may function through a variety of mechanisms. For example, such a variable flow element 1216 may comprise a structure which has a first shape when at a first temperature and a second shape when at a second temperature different from the first temperature. In certain such embodiments, the structure comprises a bi-metal or a shape-memory alloys schematically illustrated in FIG. 21. Within one temperature range, the bi-metal strip is curved relative to the direction of flow of the working fluid 1210 through the TE segment 1206, thus at least partially blocking the flow path of the working fluid 1210 through the TE segment 1206. However, as also shown in FIG. 21, within another temperature range, the bi-metal strip is substantially straight and parallel to the direction of flow of the working fluid 1210, thereby allowing the working fluid 1210 to flow past the strip relatively unimpeded.

The temperature responsive variable flow element 1216 may also function through other mechanisms. The variable flow element 1216 of certain embodiments may comprise a material which is in a first phase when at a first temperature and which is in a second phase when at a second temperature different from the first temperature. In certain such embodiments, the material comprises wax and the first phase is solid at the first temperature and the second phase is liquid at the second temperature. The variable flow element 1216 of certain embodiments may comprise a material which expands and contracts in response to temperature changes. Such a variable flow element 1216 can expand to block a flow path at a first temperature and can contract to open the flow path at a second temperature.

FIG. 22 is a flow diagram of an example method of operating a plurality of TE modules 1212 consistent with the use of a temperature responsive movable element 1208. The method 2200 comprises flowing a working fluid through a first TE segment comprising at least a first TE module, the fluid having a temperature in a first, operational block 2210. The method 2200 further comprises flowing the working fluid through a second TE segment comprising at least a second TE module when the temperature of the fluid exceeds a threshold temperature in a second operational block 2220. The method 2200 further comprises inhibiting the flow of the working fluid through the second TE segment when the temperature does not exceed the threshold temperature in a third operational block 2230. In certain such methods, the threshold temperature is selected to increase efficiency, modify electrical power output characteristics, or both, of the plurality of TE modules.

Various embodiments of the present invention have been described above. Although this invention has been described with reference to these specific embodiments, the descriptions are intended to be illustrative of the invention and are not intended to be limiting. Various modifications and applications may occur to those skilled in the art without departing from the true spirit and scope of the invention as defined in the appended claims.

1. A thermoelectric generator comprising:
a first thermoelectric segment comprising at least one thermoelectric module, the first thermoelectric segment having a working fluid flowing therethrough with a fluid pressure;
a second thermoelectric segment comprising at least one thermoelectric module, the second thermoelectric segment configurable to allow the working fluid to flow therethrough;
at least a first variable flow element movable upon application of the fluid pressure to the first variable flow element, the first variable flow element modifying a flow resistance of the second thermoelectric segment to flow of the working fluid therethrough.

2. The thermoelectric generator of claim 1, wherein movement of the first variable flow element modifies a delivery of thermal power or heat flux to the at least one thermoelectric module of the second thermoelectric segment.

3. The thermoelectric generator of claim 1, wherein movement of the first variable flow element modifies a rate of removal of waste heat from the at least one thermoelectric module of the second thermoelectric segment.

4-7. (canceled)

8. The thermoelectric generator of claim 1, wherein the first variable flow element comprises a valve.

9. (canceled)

10. The thermoelectric generator of claim 1, further comprising a conduit configurable to allow the working fluid to flow therethrough.

11. The thermoelectric generator of claim 10, further comprising a second variable flow element, the second variable flow element movable upon application of the fluid pressure to the second variable flow element, the second variable flow element modifying at least a flow resistance of the conduit to flow of the working fluid therethrough.

12-15. (canceled)

16. A thermoelectric generator comprising:
a first thermoelectric segment having at least one thermoelectric module;
a second thermoelectric segment having at least one thermoelectric module;
a movable element positionabIe in multiple positions comprising:
a first position permitting flow of a working fluid through the first thermoelectric segment while simultaneously permitting flow of the working fluid through the second thermoelectric segment;
a second position inhibiting flow of the working fluid through the first thermoelectric segment while simultaneously permitting flow of the working fluid through the second thermoelectric segment;
a third position inhibiting flow of the working fluid through the first thermoelectric segment while simultaneously inhibiting flow of the working fluid through the second thermoelectric segment.

17. The thermoelectric generator of claim 16, wherein the position of the movable element is selectable to modify the delivery of thermal power from the working fluid to the first thermoelectric segment and to the second thermoelectric segment.

18. The thermoelectric generator of claim 16, wherein the position of the movable element is selectable to modify the rate of removal of waste heat from the first thermoelectric segment and from the second thermoelectric segment.

19. The thermoelectric generator of claim 16, further comprising a controller, wherein the movable element is responsive to signals received from the controller by moving among the multiple positions.

20. The thermoelectric generator of claim 19, wherein the controller is in communication with a thermal power delivery system or a thermal power source or both, the thermal power delivery system delivering thermal power from the thermal power source to the thermoelectric generator.

21. (canceled)

22. (canceled)

23. The thermoelectric generator of claim 19, wherein the controller receives signals from one or more sensors.

24-34. (canceled)

35. A thermoelectric generator comprising:
a plurality of thermoelectric segments comprising:
a first thermoelectric segment;
a second thermoelectric segment; and
a conduit; wherein at least two of the first thermoelectric[[TE]] segment, the second thermoelectric[[TE]] segment, and the conduit each comprises at least one thermoelectric module; and
a movable element positionable in multiple positions comprising:
a first position permitting flow of a working fluid through the first thermoelectric segment while simultaneously permitting flow of the working fluid through the second thermoelectric segment and simultaneously permitting flow of the working fluid through the conduit;
a second position inhibiting flow of the working fluid through the first thermoelectric segment while simultaneously permitting flow of the working fluid through the second thermoelectric segment and simultaneously permitting flow of the working fluid through the conduit;
a third position inhibiting flow of the working fluid through the first thermoelectric segment while simultaneously inhibiting flow of the working fluid through the second thermoelectric segment and simultaneously permitting flow of the working fluid through the conduit; and
a fourth position inhibiting flow of the working fluid through the first thermoelectric segment while simultaneously inhibiting flow of the working fluid through the second thermoelectric segment and simultaneously inhibiting flow of the working fluid through the conduit.

36. The thermoelectric generator of claim 35, wherein each of the first thermoelectric[[TE]] segment, the second thermoelectric[[TE]] segment, and the conduit comprises at least one thermoelectric module,

37. The thermoelectric generator of claim 35, wherein the conduit does not comprise a thermoelectric module.

38. A method of operating a plurality of thermoelectric modules, the method comprising:
flowing a working fluid through a first thermoelectric segment comprising at least a first thermoelectric module, the fluid having a fluid pressure;
flowing the working fluid through a second thermoelectric segment comprising at least a second thermoelectric module when the fluid pressure of the fluid exceeds a threshold pressure; and
inhibiting the flow of the working fluid through the second thermoelectric segment when the fluid pressure of the fluid does not exceed the threshold pressure.

39. The method of claim 38, further comprising selecting the threshold pressure to increase efficiency, modify electrical power output characteristics, or both, of the plurality of thermoelectric modules.

40. (canceled)

41. (canceled)

42. A method of operating a plurality of thermoelectric modules, the method comprising:
varying both the flow of working fluid through a first thermoelectric segment comprising at least a first thermoelectric module and the flow of working fluid through a second thermoelectric segment comprising at least a second thermoelectric module by selecting a position for a moveable element from a plurality of positions comprising:
a first position permitting flow through the first thermoelectric segment while simultaneously permitting flow through the second thermoelectric segment;
a second position inhibiting flow through the first thermoelectric segment while simultaneously permitting flow through the second thermoelectric segment; and
a third position inhibiting flow through the first thermoelectric segment while simultaneously inhibiting flow through the second thermoelectric segment.

43. The method of claim 42, wherein the position of the movable element is selected to increase efficiency, modify electrical power output characteristics, or both, of the plurality of thermoelectric modules.

44. (canceled)

45. (canceled)

46. A thermoelectric generator comprising:
a first thermoelectric segment comprising at least one thermoelectric module, the first thermoelectric segment having a working fluid flowing therethrough, the fluid having a temperature;
a second thermoelectric segment comprising at least one thermoelectric module, the second thermoelectric segment configurable to allow the working fluid to flow therethrough;
at least a first variable flow element configured to move in response to a temperature of the first variable flow element, the first variable flow element modifying a flow resistance of the second thermoelectric segment to flow of the working fluid therethrough.

47. The thermoelectric generator of claim 46, wherein movement of the first variable flow element modifies a delivery of thermal power or heat flux to the at least one thermoelectric module of the second thermoelectric segment.

48. The thermoelectric generator of claim 46, wherein movement of the first variable flow element modifies a rate of removal of waste heat from the at least one thermoelectric module of the second thermoelectric segment.

49. The thermoelectric generator of claim 46, wherein the first variable flow element comprises a structure which has a first shape when at a first temperature and a second shape when at a second temperature different from the first temperature.

50-53. (canceled)

54. A method of operating a plurality of thermoelectric modules, the method comprising:
flowing a working fluid through a first thermoelectric segment comprising at least a first thermoelectric module, the working fluid having a temperature;
flowing the working fluid through a second thermoelectric segment comprising at least a second thermoelectric module when the temperature of the working fluid exceeds a threshold temperature; and
inhibiting the flow of the working fluid through the second thermoelectric segment when the temperature does not exceed the threshold temperature.

55. The method of claim 54, further comprising selecting the threshold temperature to increase an efficiency, modify electrical power output characteristics, or both, of the plurality of thermoelectric modules.

56. A thermoelectric generator comprising:
an input portion configured to allow a working fluid to flow therethrough;
an output portion configured to allow the working fluid to flow therethrough;
a plurality of elongate thermoelectric segments substantially parallel to one another, at least one of the thermoelectric segments comprising at least one thermoelectric module, each thermoelectric segment configurable to allow the working fluid to flow therethrough from the input portion to the output portion; and
at least one movable element positionable to allow flow of the working fluid through at least a first thermoelectric segment of the plurality of thermoelectric segments and to inhibit flow of the working fluid through at least a second thermoelectric segment of the plurality of thermoelectric segments.

57-62. (canceled)

63. The thermoelectric generator of claim 56, wherein the at least one movable element is positionable in multiple positions comprising:
a first position simultaneously allowing flow of a working fluid through the first thermoelectric segment and the second thermoelectric segment;
a second position allowing flow of the working fluid through the first thermoelectric segment while simultaneously inhibiting flow of the working fluid through the second thermoelectric segment; and
a third position simultaneously inhibiting flow of the working fluid through the first thermoelectric segment and the second thermoelectric segment.

64-67. (canceled)
